(19) United States
(12) Patent Application Publication
(10) Pub. No.: US 2026/0026200 A1
(43) Pub. Date: Jan. 22, 2026

(54) DISPLAY DEVICE, ELECTRONIC DEVICE USING THE SAME AND METHOD FOR FABRICATING THE SAME

(71) Applicant: Samsung Display Co., Ltd., Yongin-si (KR)

(72) Inventors: Dae Ho LEE, Yongin-si (KR); Young Min KIM, Yongin-si (KR); Hae Il PARK, Yongin-si (KR)

(21) Appl. No.: 19/184,760

(22) Filed: Apr. 21, 2025

(30) Foreign Application Priority Data
Jul. 17, 2024 (KR) 10-2024-0094674
Nov. 22, 2024 (KR) 10-2024-0168398

(51) Int. Cl. H10K 59/122; H10K 59/12; H10K 59/80; H10K 102/10

(52) U.S. Cl. CPC H10K 59/122; H10K 59/1201; H10K 59/80515; H10K 2102/101

(57) ABSTRACT

A display device includes a substrate including an emission area and a non-emission area; a pixel defining layer on one surface of the substrate; a first anode electrode and a second anode electrode on the emission area of the substrate and spaced apart from each other with the pixel defining layer therebetween; a first light emitting element layer on the first anode electrode and a second light emitting element layer on the second anode electrode; and an insulating layer on the pixel defining layer and between the first light emitting element layer and the second light emitting element layer spaced apart from each other, where the insulating layer includes: a flat portion in contact with the pixel defining layer; and a tip extending from one side of the flat portion and spaced apart from the pixel defining layer, where a lower surface of the tip is a curved surface.

### CROSS-REFERENCE TO RELATED APPLICATION

The present application claims priority to and the benefit of Korean Patent Application No. 10-2024-0094674, filed on Jul. 17, 2024, and Korean Patent Application No. 10-2024-0168398, filed on Nov. 22, 2024, in the Korean Intellectual Property Office, the content of each of which is incorporated herein by reference.

### BACKGROUND

### 1. Field

One or more aspects of embodiments of the present disclosure are directed toward a display device, an electronic device including the display device, and a method for fabricating the display device.

### 2. Description of the Related Art

Recently, demand for display devices for displaying images has increased and diversified. For example, display devices have been applied to various electronic devices such as smartphones, digital cameras, laptop computers, navigation devices, and/or smart televisions. The display devices may be flat panel display devices such as liquid crystal display devices, field emission display devices, and/or organic light emitting display devices. Among flat panel display devices, a light emitting display device may display an image without a backlight unit providing light to a display panel because each of pixels of the display panel includes light emitting elements that may emit light by themselves.

### SUMMARY

One or more aspects of embodiments of the present disclosure provide a high-resolution display device in which a leakage current defect is solved or substantially resolved, an electronic device including the display device, and a method for fabricating the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given herein below.

According to one or more embodiments of the present disclosure, a display device includes a substrate including an emission area and a non-emission area; a pixel defining layer positioned on one surface of the substrate; a first anode electrode and a second anode electrode positioned on the emission area of the substrate and spaced apart from each other with the pixel defining layer interposed therebetween; a first light emitting element layer positioned on the first anode electrode and a second light emitting element layer positioned on the second anode electrode; and an insulating layer positioned on the pixel defining layer and between the first light emitting element layer and the second light emitting element layer that are spaced apart from each other (e.g., an insulating layer allowing the first light emitting element layer and the second light emitting element layer to be spaced apart from each other), wherein the insulating layer includes: a flat portion in contact with the pixel defining layer; and a tip extending from one side of the flat portion and positioned to be spaced apart from the pixel defining layer, where a lower surface of the tip is a curved surface.

In one or more embodiments, the lower surface of the tip and the pixel defining layer may be in contact with each other and may form an acute angle (e.g., at a contact point where the lower surface of the tip and the pixel defining layer may be in contact with each other, a gradient of the lower surface of the tip is an acute angle).

In one or more embodiments, a distance between the pixel defining layer and the lower surface of the tip may decrease (e.g., become smaller) from an edge (e.g., outer edge) of the tip toward the flat portion.

In one or more embodiments, the pixel defining layer may overlap the non- emission area and may define an opening, and the insulating layer may not overlap the opening in a direction perpendicular to (e.g., crossing) one surface of the substrate.

In one or more embodiments, the tip of the insulating layer may further include an upper surface opposite (e.g., opposing) the lower surface, and the upper surface of the tip of the insulating layer may be a curved surface.

In one or more embodiments, the first light emitting element layer and the second light emitting element layer may be in contact with the insulating layer.

In one or more embodiments, each of the first light emitting element layer and the second light emitting element layer may include at least one selected from among a hole injection layer, a hole transporting layer, and a charge transporting layer.

In one or more embodiments, the pixel defining layer may include a first surface facing the insulating layer, and the first surface may include a first portion in contact with the first light emitting element layer; a second portion in contact with the second light emitting element layer; and a third portion in contact with the flat portion of the insulating layer.

In one or more embodiments, the first portion and the second portion may be spaced apart from each other with the third portion interposed therebetween.

In one or more embodiments, the first anode electrode and the second anode electrode may be positioned at different heights.

In one or more embodiments, the display device may further include a first residual pattern positioned on the first anode electrode so as to be in contact with the first anode electrode; and a second residual pattern positioned on the second anode electrode so as to be in contact with the second anode electrode, wherein the first residual pattern and the second residual pattern may be positioned to surround an opening defined by the pixel defining layer, and each of the first residual pattern and the second residual pattern may include a transparent conductive material.

According to one or more embodiments of the present disclosure, a method for fabricating a display device includes forming a temporary protective layer on an anode electrode and forming a pixel defining layer defining an opening; forming a photoresist pattern on the anode electrode and forming an insulating layer on the photoresist pattern; removing the insulating layer overlapping the opening and removing the photoresist pattern; and forming a light emitting element layer and a cathode electrode on the anode electrode.

In one or more embodiments, in the forming of the photoresist pattern on the anode electrode and the forming of the insulating layer on the photoresist pattern, the insulating layer may be positioned the photoresist pattern so as to be in contact with the photoresist pattern.

In one or more embodiments, in the removing of the insulating layer overlapping the opening and the removing of the photoresist pattern, the insulating layer may include a flat portion in contact with the pixel defining layer and tips positioned to be connected to both (e.g., simultaneously) sides (e.g., opposite sides) of the flat portion and protruding toward the opening, the tips of the insulating layer may be spaced apart from the pixel defining layer in a direction perpendicular to (e.g., crossing) one surface of the pixel defining layer, and the tips of the insulating layer may have a set or predetermined curvature.

According to one or more embodiments of the present disclosure, an electronic device includes at least one display device including a substrate including an emission area and a non-emission area; and at least one selected from among a display module, a processor, a memory, and a power module connected to the at least one display device, wherein the at least one display device includes: a pixel defining layer positioned on one surface of the substrate; a first anode electrode and a second anode electrode positioned on the emission area of the substrate and spaced apart from each other with the pixel defining layer interposed therebetween; a first light emitting element layer positioned on the first anode electrode and a second light emitting element layer positioned on the second anode electrode; and an insulating layer positioned on the pixel defining layer and between the first light emitting element layer and the second light emitting element layer that may be spaced apart from each other (e.g., allowing the first light emitting element layer and the second light emitting element layer to be spaced apart from each other), the insulating layer includes: a flat portion in contact with the pixel defining layer; and a tip extending from one side of the flat portion and positioned to be spaced apart from the pixel defining layer, where a lower surface of the tip is a curved surface.

In one or more embodiments, the lower surface of the tip and the pixel defining layer may be in contact with each other and may form an acute angle (e.g., at a contact point where the lower surface of the tip and the pixel defining layer are in contact with each other, a gradient of the lower surface of the tip may be an acute angle).

In one or more embodiments, a distance between the pixel defining layer and the lower surface of the tip may decrease (e.g., become smaller) from an edge (e.g., outer edge) of the tip toward the flat portion.

In one or more embodiments, the pixel defining layer may overlap the non-emission area and may define an opening, and the insulating layer may not overlap the opening in a direction perpendicular to (e.g., crossing) one surface of the substrate.

In one or more embodiments, the first light emitting element layer and the second light emitting element layer may be in contact with the insulating layer.

In one or more embodiments, each of the first light emitting element layer and the second light emitting element layer may include at least one selected from among a hole injection layer, a hole transporting layer, and a charge transporting layer.

More detailed contents of other embodiments are described in a detailed description and are illustrated in the drawings.

With a display device and a method for fabricating the same according to one or more embodiments, it is possible to provide a high-resolution display device in which a leakage current defect is solved or substantially reduced, and an electronic device using the display device.

The effects of the present disclosure are not limited to the aforementioned effects, and one or more suitable other effects will become more apparent to one of ordinary skill in the art to which the present disclosure pertains by referencing the detailed description of the present disclosure provided herein.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or more embodiments;

FIG. 2 is a cross-sectional view illustrating the display device according to one or more embodiments;

FIG. 3 is a plan view illustrating a display unit of the display device according to one or more embodiments;

FIG. 4 is a block diagram illustrating a display panel and a display driver according to one or more embodiments;

FIG. 5 is a plan view illustrating an arrangement of a plurality of pixels positioned in a display area of FIGS. 3 and 4;

FIG. 6 is a cross-sectional view of the display device according to one or more embodiments taken along the line X1-X1′ in FIG. 5;

FIG. 7 is an enlarged cross-sectional view of a light emitting element in FIG. 6;

FIG. 8 is an enlarged cross-sectional view of a display element layer of a portion overlapping a non-emission area positioned between a first emission area and a second emission area in FIG. 6;

FIG. 9 is an enlarged cross-sectional view of an insulating layer in FIG. 8;

FIG. 10 is an enlarged cross-sectional view of a display element layer of a portion overlapping a non-emission area positioned between the second emission area and a third emission area in FIG. 6;

FIG. 11 is a cross-sectional view of a display device according to one or more other embodiments taken along the line X1-X1′ in FIG. 5;

FIG. 12 is an enlarged cross-sectional view of a light emitting element in FIG. 11;

FIG. 13 is a flowchart illustrating a method for fabricating the display element layer in FIG. 6;

FIGS. 14-16 are cross-sectional views illustrating act S100 of FIG. 13;

FIG. 17 is a cross-sectional view illustrating act S200 of FIG. 13;

FIGS. 18-20 are each a cross-sectional view illustrating act S300 of FIG. 13;

FIG. 21 is a cross-sectional view illustrating act S400 of FIG. 13;

FIG. 22 is a block diagram of an electronic device according to one or more embodiments; and

FIG. 23 is schematic views of electronic devices according to one or more suitable embodiments.

### DETAILED DESCRIPTION

The disclosure will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” and/or the like to another element, the element may be in “electrical contact” and/or in “physical contact” with another element; and/or in “indirect contact” or in “direct contact” with another element.

Although the terms “first,” “second,” and/or the like may be used herein to describe one or more suitable types (kinds) of elements, these elements should not be limited by these terms. These terms are used to distinguish one element from another element. Thus, a first element could be termed a second element without departing from the teachings of the disclosure.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and/or the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both (e.g., simultaneously) an orientation of above and below. Furthermore, the apparatus may be otherwise oriented (e.g., rotated 90 degrees or at other orientations), and, as such, the spatially relative descriptors used herein interpreted accordingly.

As used herein, expressions such as “at least one of”, “one of”, and “selected from”, when preceding a list of elements, modify the entire list of elements and do not modify the individual elements of the list. In the specification and the claims, the phrase “at least one of” is intended to include the meaning of “at least one selected from the group of” for the purpose of its meaning and interpretation. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof. In the specification and the claims, the term “and/or” is intended to include any combination of the terms “and” and “or” for the purpose of its meaning and interpretation. For example, “A and/or B” may be understood to refer to “A, B, or A and B.” The terms “and” and “or” may be used in the conjunctive or disjunctive sense and may be understood to be equivalent to “and/or.”

Further, the use of “may” when describing embodiments of the present disclosure refers to “one or more embodiments of the present disclosure”.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively (or substantially) formal sense unless clearly defined in the specification.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments will be described with reference to the accompanying drawings.

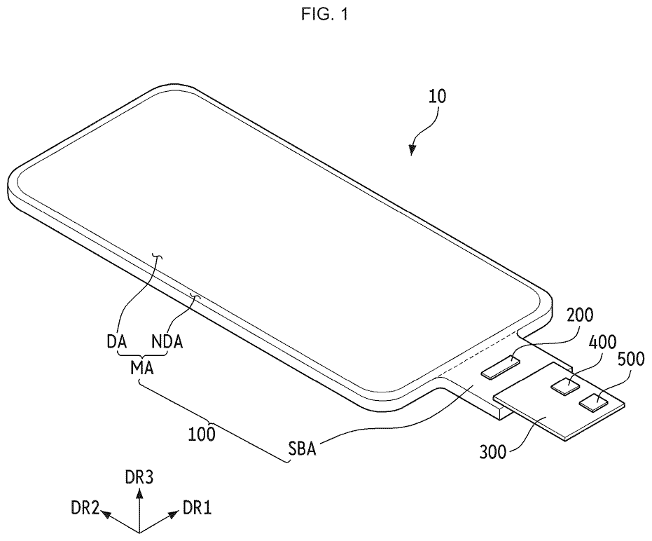

FIG. 1 is a perspective view illustrating a display device according to one or more embodiments.

Referring to FIG. 1, a display device 10 may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 may be applied as a display unit of televisions, laptop computers, monitors, billboards, and/or the Internet of Things (IOTs). In one or more embodiments, the display device 10 may be applied to wearable devices such as smart watches, watch phones, glasses-type or kind displays, and/or head mounted displays (HMDs).

The display device 10 may have a shape similar to a rectangular shape in plan view. For example, the display device 10 may have a shape similar to a rectangular shape, in plan view, having short sides in a first direction DR1 and long sides in a second direction DR2. A corner where the short side in the first direction DR1 and the long side in the second direction DR2 meet may be rounded with a set or predetermined curvature or may be right-angled. The shape of the display device 10 in plan view is not limited to the rectangular shape, and may be any suitable shape similar to other polygonal shapes, a circular shape, and/or an elliptical shape.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels configured to display an image and a non-display area NDA arranged around the display area DA. The display area DA may be to emit light from a plurality of emission areas or a plurality of opening areas. For example, the display panel 100 may include pixel circuits including switching elements, a pixel defining film defining the emission areas or the opening areas, and self-light emitting elements.

For example, the self-light emitting element may include at least one selected from among an organic light emitting diode (LED) including an organic light emitting layer, a quantum dot LED including a quantum dot light emitting layer, an inorganic LED including an inorganic semiconductor, and a micro LED, but the present disclosure is not limited thereto.

The non-display area NDA may be an area outside the display area DA. The non-display area NDA may be defined as an edge area of the main area MA of the display panel 100. The non-display area NDA may include a gate driver for supplying gate signals to gate lines and fan-out lines connecting the display driver 200 and the display area DA to each other.

The sub-area SBA may extend from one side of the main area MA. The sub-area SBA may include a flexible material that may be bent, folded, and/or rolled. For example, when the sub-area SBA is bent, the sub-area SBA may overlap the main area MA in a thickness direction (e.g., a third direction DR3). The sub-area SBA may include the display driver 200 and pad portions connected to the circuit board 300. In one or more embodiments, the sub-area SBA may not be provided, and the display driver 200 and the pad portions may be arranged in the non-display area NDA.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and mounted on the display panel 100 by a suitable method including a chip on glass (COG) manner, a chip on plastic (COP) manner, and/or an ultrasonic bonding manner. As an example, the display driver 200 may be arranged in the sub-area SBA, and may overlap the main area MA in the thickness direction (third direction DR3) by bending of the sub-area SBA (e.g., when the sub-area SBA is bent). In some embodiments, the display driver 200 may be mounted on the circuit board 300.

The circuit board 300 may be attached onto the pad portions of the display panel 100 using an anisotropic conductive film (ACF). Lead lines of the circuit board 300 may be electrically connected to the pad portions of the display panel 100. The circuit board 300 may be a flexible printed circuit board, a printed circuit board, and/or a flexible film such as a chip on film.

The touch driver 400 may be mounted on the circuit board 300. The touch driver 400 may be electrically connected to a touch sensing unit of the display panel 100. The touch driver 400 may supply touch driving signals to a plurality of touch electrodes of the touch sensing unit and sense change amounts in capacitance between the plurality of touch electrodes. For example, the touch driving signal may be a pulse signal having a set or predetermined frequency. The touch driver 400 may decide (or determine) whether or not an input has occurred and calculate input coordinates, based on the change amounts in capacitance between the plurality of touch electrodes. The touch driver 400 may be formed as an integrated circuit (IC).

The power supply unit 500 may be arranged on the circuit board 300 and may supply source voltages to the display driver 200 and the display panel 100. The power supply unit 500 may generate a driving voltage and supply the driving voltage to a driving voltage line VDL, may generate initialization voltages (e.g., a first initialization voltage and a second initialization voltage) and supply the initialization voltages to initialization voltage lines (e.g., a first initialization voltage line VIL1 and a second initialization voltage line VIL2), and may generate a common voltage and supply the common voltage to a common electrode (e.g., a cathode electrode) common to light emitting elements of a plurality of pixels. For example, the driving voltage may be a high (e.g., suitably high) potential voltage for driving the light emitting element, and the common voltage may be a low (e.g., suitably low) potential voltage for driving the light emitting element.

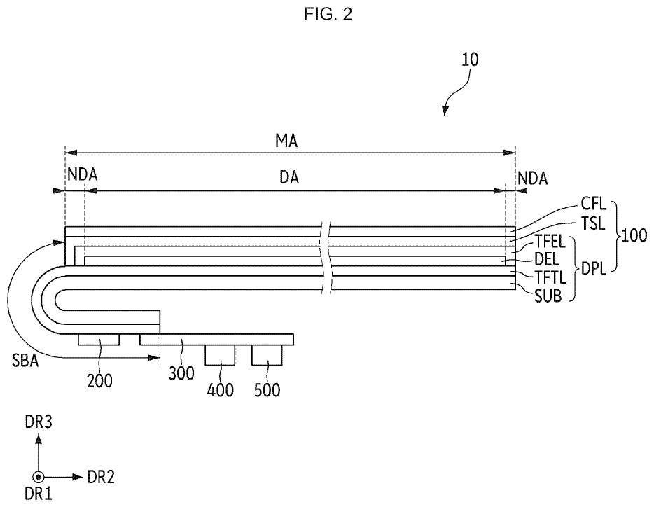

FIG. 2 is a cross-sectional view illustrating the display device according to one or more embodiments.

Referring to FIG. 2, the display panel 100 may include a display layer DPL, a touch sensing layer TSL, and a color filter layer CFL. The display layer DPL may include a substrate SUB, a transistor layer TFTL, a display element layer DEL, and an encapsulation layer TFEL.

The substrate SUB may be a base substrate or a base member. The substrate SUB may be a flexible substrate that may be bent, folded, and/or rolled. For example, the substrate SUB may include a polymer resin such as polyimide (PI), but the present disclosure is not limited thereto. In some embodiments, the substrate SUB may include a glass material and/or a metal material.

The transistor layer TFTL may be arranged on the substrate SUB. The transistor layer TFTL may include a plurality of transistors (e.g., thin film transistors) constituting pixel circuits of the pixels. The transistor layer TFTL may further include gate lines, data lines, power lines, gate control lines, fan-out lines connecting the display driver 200 and the data lines to each other, and lead lines connecting the display driver 200 and the pad portions to each other.

The transistor layer TFTL may be arranged in the display area DA, the non-display area NDA, and the sub-area SBA. The transistors of each of the pixels, the gate lines, the data lines, and the power lines of the transistor layer TFTL may be arranged in the display area DA. The gate control lines and the fan-out lines of the transistor layer TFTL may be arranged in the non-display area NDA. The lead lines of the transistor layer TFTL may be arranged in the sub-area SBA.

The display element layer DEL may be arranged on the transistor layer TFTL. The display element layer DEL may include a plurality of light emitting elements in which a pixel electrode (e.g., an anode electrode), a light emitting layer, and a common electrode (e.g., a cathode electrode) are sequentially stacked to emit light and a pixel defining layer defining the pixels. The plurality of light emitting elements of the display element layer DEL may be arranged in the display area DA.

The light emitting layer may be an organic light emitting layer including an organic material. The light emitting layer may include a hole transporting layer, an organic light emitting layer, and an electron transporting layer. When the pixel electrode receives a set or predetermined voltage through the transistor of the transistor layer TFTL and the common electrode receives a cathode voltage, holes and electrons may move to the organic light emitting layer through the hole transporting layer and the electron transporting layer, respectively, and may be combined with each other in the organic light emitting layer to emit light.

In one or more embodiments, the plurality of light emitting elements may include quantum dot light emitting diodes each including a quantum dot light emitting layer, inorganic light emitting diodes each including an inorganic semiconductor, and/or micro light emitting diodes.

The encapsulation layer TFEL may cover an upper surface and side surfaces of the display element layer DEL, and may protect the display element layer DEL. The encapsulation layer TFEL may include at least one inorganic film and at least one organic film for encapsulating the display element layer DEL.

The touch sensing layer TSL may be arranged on the encapsulation layer TFEL. The touch sensing layer TSL may include a plurality of touch electrodes for sensing a user's touch in a capacitance manner and touch lines connecting the plurality of touch electrodes and the touch driver 400 to each other. For example, the touch sensing layer TSL may sense the user's touch in a mutual capacitance manner and/or a self-capacitance manner. The touch sensing layer TSL may not be provided according to one or more embodiments.

The color filter layer CFL may be arranged on the touch sensing layer TSL. The color filter layer CFL may include a plurality of color filters respectively corresponding to the plurality of emission areas. Each of the color filters may selectively transmit light of a set or specific wavelength therethrough and block, reduce or absorb light of other wavelengths. The color filter layer CFL may be to absorb some of light introduced from the outside of the display device 10 to reduce reflected light by external light. Accordingly, the color filter layer CFL may prevent or reduce distortion of colors due to external light reflection.

Because the color filter layer CFL is directly arranged on the touch sensing layer TSL, the display device 10 may not require a separate substrate for the color filter layer CFL. Accordingly, a thickness of the display device 10 may be relatively decreased.

The sub-area SBA of the display panel 100 may extend from one side of the main area MA. The sub-area SBA may include a flexible material that may be bent, folded, and/or rolled. For example, when the sub-area SBA is bent, the sub-area SBA may overlap the main area MA in the thickness direction (third direction DR3). The sub-area SBA may include the display driver 200 and the pad portions connected to the circuit board 300.

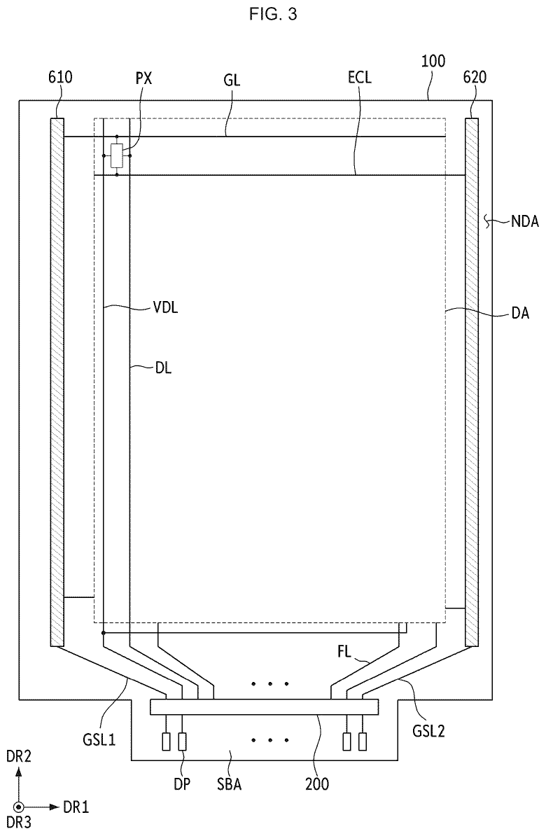

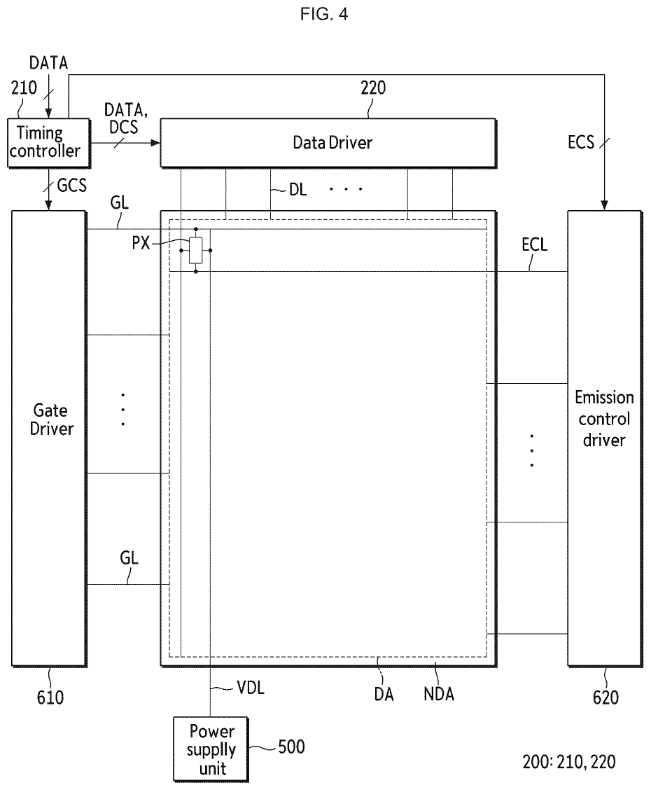

FIG. 3 is a plan view illustrating a display unit of the display device according to one or more embodiments, and FIG. 4 is a block diagram illustrating a display panel and a display driver according to one or more embodiments.

Referring to FIGS. 3 and 4, the display panel 100 may include a display area DA and a non-display area NDA.

The display area DA may include a plurality of pixels PX and a plurality of driving voltage lines VDL connected to the plurality of pixels PX, and a plurality of gate lines GL, a plurality of emission control lines ECL, and a plurality of data lines DL of a plurality of common voltage lines.

Each of the plurality of pixels PX may be connected to the gate line GL, the data line DL, the emission control line ECL, the driving voltage line VDL, and the common voltage line. Each of the plurality of pixels PX may include at least one transistor, a light emitting element, and a capacitor.

The gate lines GL may extend in the first direction DR1, and may be spaced apart from each other in the second direction DR2 crossing the first direction DR1. The gate lines GL may be arranged along the second direction DR2. The gate lines GL may sequentially supply gate signals to the plurality of pixels PX.

The emission control lines ECL may extend in the first direction DR1, and may be spaced apart from each other in the second direction DR2. The emission control lines ECL may be arranged along the second direction DR2. The emission control lines ECL may sequentially supply emission signals to the plurality of pixels PX.

The data lines DL may extend in the second direction DR2, and may be spaced apart from each other in the first direction DR1. The data lines DTL may be arranged along the first direction DR1. The data lines DL may supply data voltages to the plurality of pixels PX. The data voltage may determine luminance of each of the plurality of pixels PX.

The driving voltage lines VDL may extend in the second direction DR2, and may be spaced apart from each other in the first direction DR1. The driving voltage lines VDL may be arranged along the first direction DR1. The driving voltage lines VDL may supply a first driving voltage to the plurality of pixels PX. The first driving voltage may be a high potential voltage for driving the light emitting elements of the pixels PX.

The non-display areas NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltages received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from one side of the non-display area NDA. The sub-area SBA may include the display driver 200 and pad portions DP. The pad portion DP may be arranged more adjacent (e.g., closer) to an edge of one side of the sub-area SBA than the display driver 200 is. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may control an operation timing of the data driver 220 by generating a data control signal DCS based on the timing signals, may control an operation timing of the gate driver 610 by generating the gate control signal GCS based on the timing signals, and may control an operation timing of the emission control driver 620 by generating the emission control signal ECS based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals of the gate driver 610 may select pixels PX to which the data voltages are supplied, and the selected pixels PX may receive the data voltages through the data lines DL.

The power supply unit 500 may be arranged on the circuit board 300, and may supply source voltages to the display driver 200 and the display panel 100. The power supply unit 500 may generate a driving voltage and supply the driving voltage to the driving voltage line VDL, may generate an initialization voltage and supply the initialization voltage to an initialization voltage line, and may generate a common voltage and supply the common voltage to a common electrode common to light emitting elements of the plurality of pixels.

The gate driver 610 may be arranged outside one side of the display area DA and/or on one side of the non-display area NDA, and the emission control driver 620 may be arranged outside the other side of the display area DA and/or on the other side of the non-display area NDA, but the present disclosure is not limited thereto. In one or more embodiments, the gate driver 610 and the emission control driver 620 may be arranged on any one of one side or the other side of the non-display area NDA.

The gate driver 610 may include a plurality of transistors to generate gate signals based on the gate control signal GCS. The emission control driver 620 may include a plurality of transistors to generate emission signals based on the emission control signal ECS. For example, the transistors of the gate driver 610 and the transistors of the emission control driver 620 may be formed at the same layer (e.g., on the same layer and/or on the same level) as the transistor of each of the pixels PX. The gate driver 610 may supply the gate signals to the gate lines GL, and the emission control driver 620 may supply the emission signals to the emission control lines ECL.

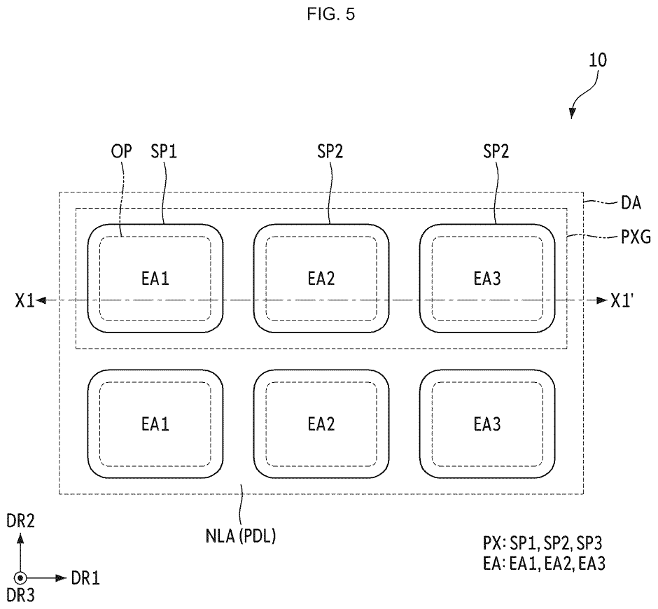

FIG. 5 is a plan view illustrating an arrangement of a plurality of pixels positioned in a display area of FIGS. 3 and 4.

Referring to FIG. 5, in one or more embodiments, the pixel PX may be positioned in a portion overlapping the display area DA. The number of pixel PX positioned in the portion overlapping the display area DA may be plural. The pixel PX may include an emission area EA.

The emission area EA may include first emission areas EA1, second emission areas EA2, and third emission areas EA3 that may be to emit light of different colors. In one or more embodiments, the first emission area EA1 may be to emit red light, which is light of a first color, the second emission area EA2 may be to emit green light, which is light of a second color, and the third emission area EA3 may be to emit blue light, which is light of a third color, but the present disclosure is not limited thereto.

In some embodiments, a first sub-pixel SP1 including at least one first emission area EA1, a second sub-pixel SP2 including at least one second emission area EA2, and a third sub-pixel SP3 including at least one third emission area EA3, which are arranged adjacent to each other, may constitute one pixel group PXG. The pixel group PXG may be a minimum unit to emit white light. However, types (kinds) and/or the number of emission areas EA constituting the pixel group PXG may be variously suitably changed according to one or more embodiments.

It has been illustrated in FIG. 5 that sizes and/or shapes of the first to third emission areas EA1, EA2, and EA3 are substantially the same as each other, but the present disclosure is not limited thereto. For example, sizes and/or shapes of the first to third emission areas EA1, EA2, and EA3 may be freely adjusted according to desired or required characteristics.

A non-emission area NLA according to one or more embodiments may be positioned to surround each of the first to third emission areas EA1, EA2, and EA3. The non-emission area NLA may assist in preventing or reducing light emitted from each of the first to third emission areas EA1, EA2, and EA3 from being mixed with each other.

In plan view, a pixel defining layer PDL may be positioned in a portion overlapping the non-emission area NLA. The pixel defining layer PDL may define an opening OP, and in plan view, the pixel defining layer PDL may be positioned to surround the opening OP. In plan view, the opening OP may be positioned in a portion overlapping the emission area EA.

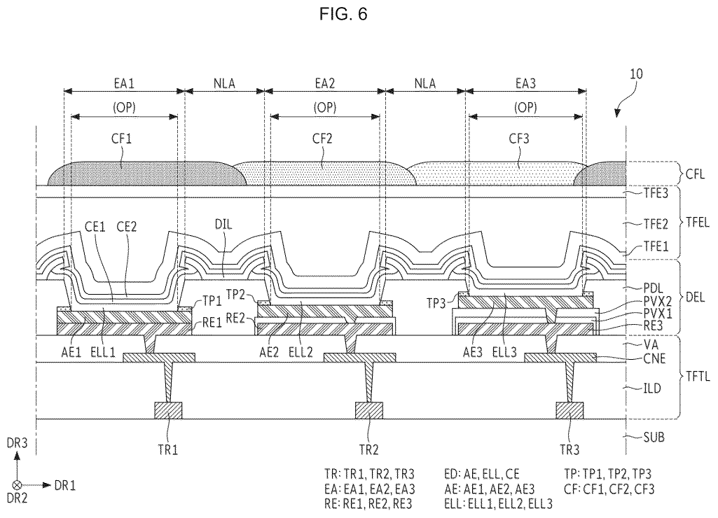

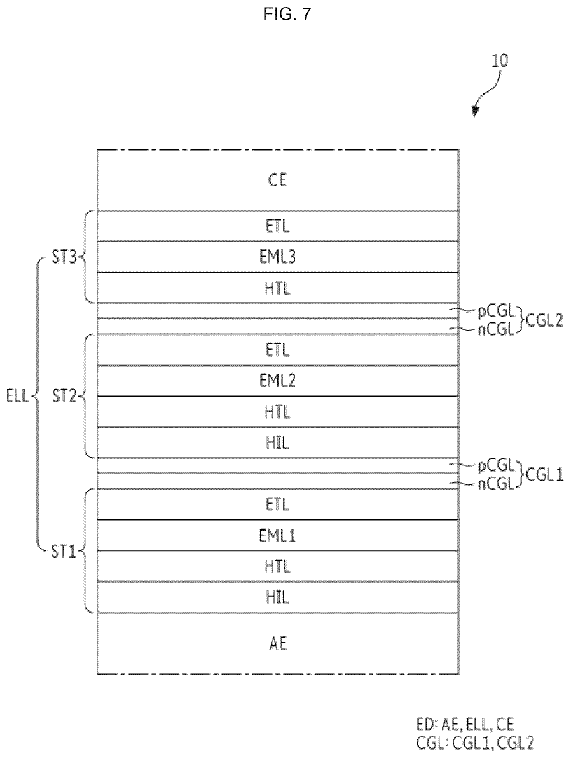

FIG. 6 is a cross-sectional view of the display device according to one or more embodiments taken along the line X1-X1′ in FIG. 5, and FIG. 7 is an enlarged cross-sectional view of a light emitting element in FIG. 6.

A cross-sectional view of the display device 10 including the substrate SUB, the display layer DPL, and the color filter layer CFL has been illustrated in FIG. 6. For convenience of explanation, a structure in which the touch sensing layer TSL of FIG. 2 is omitted is illustrated in FIG. 6 and then described, but the display device 10 may further include the touch sensing layer TSL.

Referring to FIGS. 6 and 7, the transistor layer TFTL may be arranged on the substrate SUB. The transistor layer TFTL may include a plurality of transistors TR, an interlayer insulating layer ILD, a connection electrode CNE, and a via layer VA.

In one or more embodiments, the plurality of transistors TR may be positioned on the substrate SUB. The transistor TR may be a driving transistor of the pixel PX. The transistor TR may include a first transistor TR1, a second transistor TR2, and a third transistor TR3. The first transistor TR1 may be positioned in a portion overlapping the first emission area EA1, the second transistor TR2 may be positioned in a portion overlapping the second emission area EA2, and the third transistor TR3 may be positioned in a portion overlapping the third emission area EA3. The first transistor TR1, the second transistor TR2, and the third transistor TR3 may be spaced apart from each other.

The transistor TR may include a semiconductor material. For example, the transistor TR may include polysilicon, amorphous silicon, an oxide semiconductor, and/or other suitable semiconductor materials.

The transistor TR may include an active layer including a source electrode, a drain electrode, and a channel region, and a gate electrode.

The interlayer insulating layer ILD may be arranged on the transistor TR. The interlayer insulating layer ILD may be formed as a plurality of layers stacked with a conductive material interposed therebetween.

The interlayer insulating layer ILD may include an inorganic insulating material such as silicon nitride (e.g., Si₃N₄ and/or SiNₓ), silicon oxide (e.g., SiO₂ and/or SiOₓ), silicon oxynitride (e.g., SiON), titanium oxide, aluminum oxide, and/or other suitable inorganic insulating materials.

The connection electrode CNE may be positioned on the interlayer insulating layer ILD. The connection electrode CNE may electrically connect the transistor TR and an anode electrode AE to each other.

The connection electrode CNE may be connected to the transistor TR through a contact hole penetrating through the interlayer insulating layer ILD. For example, the connection electrode CNE may be connected to the drain electrode of the transistor TR through the contact hole penetrating through the interlayer insulating layer ILD. In one or more embodiments, the connection electrode CNE may be connected to the anode electrode AE through a contact hole penetrating through the via layer VA.

The via layer VA may be positioned on the connection electrode CNE. The via layer VA may cover the connection electrode CNE, and may substantially planarize an underlying structure.

The via layer VA may include an organic material. For example, the via layer VA may include an acrylic resin, an epoxy resin, a phenolic resin, a polyamide resin, a polyimide resin, and/or the like.

The display element layer DEL may be arranged on the transistor layer TFTL. The display element layer DEL may include a reflective electrode RE, a light emitting element ED, a first element inorganic layer PVX1, a second element inorganic layer PVX2, a residual pattern TP, a pixel defining layer PDL, and an insulating layer DIL.

In one or more embodiments, the reflective electrode RE may be arranged on the via layer VA in a portion overlapping the emission area EA. The reflective electrode RE may reflect light emitted from the light emitting element ED and/or light incident from the outside.

The reflective electrode RE may include a metal layer including a metal such as silver (Ag), magnesium (Mg), aluminum (AI), platinum (Pt), palladium (Pd), gold (Au), nickel (Ni), neodymium (Nd), iridium (Ir), chromium (Cr), and/or compounds thereof. In one or more embodiments, the reflective electrode RE may further include metal oxide layers (e.g., transparent conductive oxide layers) positioned above and/or below the metal layer. For example, the reflective electrode RE may have a double-layer structure such as indium tin oxide (ITO)/Ag, Ag/ITO, ITO/Mg, and/or ITO/MgF, or a triple-layer structure such as ITO/Ag/ITO.

The reflective electrode RE may include a first reflective electrode RE1 positioned in a portion overlapping the first emission area EA1, a second reflective electrode RE2 positioned in a portion overlapping the second emission area EA2, and a third reflective electrode RE3 positioned in a portion overlapping the third emission area EA3. The first reflective electrode RE1, the second reflective electrode RE2, and the third reflective electrode RE3 may be spaced apart from each other with the pixel defining layer PDL interposed therebetween.

The first reflective electrode RE1, the second reflective electrode RE2, and the third reflective electrode RE3 may be positioned on the same line (e.g., on the same layer and/or the same level) in the first direction DR1, and may have substantially the same thickness.

In one or more embodiments, the first element inorganic layer PVX1 may be positioned on the second reflective electrode RE2 in a portion overlapping the second emission area EA2, and may be positioned on the third reflective electrode RE3 in a portion overlapping the third emission area EA3. The first element inorganic layer PVX1 may not overlap the first emission area EA1.

The first element inorganic layer PVX1 may entirely cover each of the second reflective electrodes RE2 and the third reflective electrode RE3.

The first element inorganic layer PVX1 may be a resonance auxiliary layer of a second light emitting element ED2. For example, the first element inorganic layer PVX1 may have a thickness at which constructive interference may be generated when light emitted from the second light emitting element ED2 is reflected by the second reflective electrode RE2. Accordingly, the first element inorganic layer PVX1 may improve emission efficiency of the second light emitting element ED2.

The first element inorganic layer PVX1 may be formed as an inorganic film. For example, the first element inorganic layer PVX1 may be formed as a silicon carbonitride (SiCN) and/or silicon oxide (SiOₓ)-based inorganic film (e.g., a high-transmissivity inorganic film).

In one or more embodiments, the second element inorganic layer PVX2 may be positioned on the first element inorganic layer PVX1 in a portion overlapping the third emission area EA3. The second element inorganic layer PVX2 may not overlap the first emission area EA1 and the second emission area EA2. The second element inorganic layer PVX2 may entirely cover the first element inorganic layer PVX1.

The first element inorganic layer PVX1 and the second element inorganic layer PVX2 may be resonance auxiliary layers of a third light emitting element ED3. For example, the sum of a thickness of the first element inorganic layer PVX1 and a thickness of the second element inorganic layer PVX2 may be a thickness at which constructive interference may be generated when light emitted from the third light emitting element ED3 is reflected by the third reflective electrode RE3. Accordingly, the first element inorganic layer PVX1 and the second element inorganic layer PVX2 may improve emission efficiency of the third light emitting element ED3.

The second element inorganic layer PVX2 may be formed as an inorganic film. For example, the second element inorganic layer PVX2 may be formed as a silicon carbonitride (SiCN) and/or silicon oxide (SiOₓ)-based inorganic film (e.g., a high-transmissivity inorganic film).

In one or more embodiments, the light emitting element ED may be positioned on the reflective electrode RE. The light emitting element ED may include an anode electrode AE, a light emitting element layer ELL, and a cathode electrode CE.

In one or more embodiments, the anode electrode AE may be positioned on the reflective electrode RE.

The anode electrode AE may include a first anode electrode AE1 positioned in a portion overlapping the first emission area EA1, a second anode electrode AE2 positioned in a portion overlapping the second emission area EA2, and a third anode electrode AE3 positioned in a portion overlapping the third emission area EA3. The first anode electrode AE1, the second anode electrode AE2, and the third anode electrode AE3 may be spaced apart from each other with the pixel defining layer PDL interposed therebetween.

The anode electrode AE may be made of any one selected from among copper (Cu), aluminum (AI), tungsten (W), molybdenum (Mo), chromium (Cr), gold (Au), titanium (Ti), nickel (Ni), and neodymium (Nd), alloys thereof, and/or transparent conductive oxide. For example, the anode electrode AE may include titanium nitride (TiN), ITO, and/or indium zinc oxide (IZO), but one or more embodiments of the present disclosure are not limited thereto.

The anode electrode AE may be connected to the connection electrode CNE and the transistor TR through the reflective electrode RE. For example, the first anode electrode AE1 may be connected to the connection electrode CNE and the first transistor TR1 through the first reflective electrode RE1. In one or more embodiments, the second anode electrode AE2 may be connected to the second reflective electrode RE2 through a contact hole penetrating through the first element inorganic layer PVX1, and may be connected to the connection electrode CNE and the second transistor TR2 through the second reflective electrode RE2. In one or more embodiments, the third anode electrode AE3 may be connected to the third reflective electrode RE3 through a contact hole penetrating through the first element inorganic layer PVX1 and the second element inorganic layer PVX2, and may be connected to the connection electrode CNE and the third transistor TR3 through the third reflective electrode RE3.

The first anode electrode AE1, the second anode electrode AE2, and the third anode electrode AE3 may be positioned at different heights. For example, the first anode electrode AE1 may be positioned closest to the substrate SUB among the anode electrodes AE, and the third anode electrode AE3 may be positioned farthest from the substrate SUB among the anode electrodes AE. In one or more embodiments, the second anode electrode AE2 may be positioned closer to the substrate SUB than the third anode electrode AE3, and may be positioned farther from the substrate SUB than the first anode electrode AE1.

In one or more embodiments, the pixel defining layer PDL may be positioned on the via layer VA in a portion overlapping the non-emission area NLA. The pixel defining layer PDL may cover edges of the reflective electrode RE and the anode electrode AE.

The pixel defining layer PDL may define an opening OP, and may be positioned to surround the opening OP in cross section. The pixel defining layer PDL may expose the anode electrode AE in a portion overlapping the opening OP.

The pixel defining layer PDL may include an organic material and/or an inorganic insulating material.

For example, when the pixel defining layer PDL includes the organic material, the pixel defining layer PDL may include an acrylic resin, an epoxy resin, a phenolic resin, a polyamide resin, a polyimide resin, and/or the like.

For example, when the pixel defining layer PDL includes the inorganic insulating material, the pixel defining layer PDL may include silicon nitride (e.g., Si₃N₄ and/or SiNₓ), silicon oxide (e.g., SiO₂ and/or SiOₓ), silicon oxynitride (e.g., SiON), titanium oxide, aluminum oxide, and/or other suitable inorganic insulating materials.

In one or more embodiments, the insulating layer DIL may be positioned on the pixel defining layer PDL in a portion overlapping the non-emission area NLA. The insulating layer DIL may not overlap the opening OP. The insulating layer DIL will be described in more detail herein below.

In one or more embodiments, the residual pattern TP may be positioned between the anode electrode AE and the pixel defining layer PDL in the third direction DR3. The residual pattern TP may be positioned to surround the opening OP.

The residual pattern TP may be temporarily used to protect the anode electrode AE during a fabricating process of the display device 10 (e.g., from a photo process such as light exposure), and may then remain in a form illustrated in FIG. 6. The fabricating process will be described in more detail herein below.

The residual pattern TP may include a transparent conductive material (TCO). For example, the residual pattern TP may include ITO, IZO, and/or the like.

The residual pattern TP may include a first residual pattern TP1 positioned in a portion overlapping the first emission area EA1, a second residual pattern TP2 positioned in a portion overlapping the second emission area EA2, and a third residual pattern TP3 positioned in a portion overlapping the third emission area EA3. The first residual pattern TP1, the second residual pattern TP2, and the third residual pattern TP3 may be spaced apart from each other with the pixel defining layer PDL interposed therebetween.

The first residual pattern TP1, the second residual pattern TP2, and the third residual pattern TP3 may be positioned at different heights. For example, the first residual pattern TP1 may be positioned closest to the substrate SUB, and the third residual pattern TP3 may be positioned farthest from the substrate SUB in the third direction DR3. In one or more embodiments, the second residual pattern TP2 may be positioned closer to the substrate SUB than the third residual pattern TP3, and may be positioned farther from the substrate SUB than the first residual pattern TP1.

In one or more embodiments, the light emitting element layer ELL may be positioned on the anode electrode AE. For example, the light emitting element layer ELL may include a first light emitting element layer ELL1 overlapping the first emission area EA1, a second light emitting element layer ELL2 overlapping the second emission area EA2, and a third light emitting element layer ELL3 overlapping the third emission area EA3. The first light emitting element layer ELL1, the second light emitting element layer ELL2, and the third light emitting element layer ELL3 may be spaced apart from each other with the pixel defining layer PDL and the insulating layer DIL interposed therebetween.

As illustrated in FIG. 7, the light emitting element layer ELL according to one or more embodiments may include a plurality of light emitting stacks ST. The light emitting stack ST may include a high molecular weight and/or low molecular weight organic material that are to emit light of a set or predetermined color. The light emitting stack ST may further include a metal-containing compound such as an organometallic compound, an inorganic material such as a quantum dot, and/or the like, in addition to one or more suitable organic materials. A three (3)-tandem structure including three light emitting stacks ST has been illustrated in FIG. 7, but the present embodiments are not limited thereto. The number of light emitting stacks ST may be two or less or be four or more.

The light emitting stack ST may include at least one light emitting layer EML. For example, a first light emitting stack ST1 may include a first light emitting layer EML1, a second light emitting stack ST2 may include a second light emitting layer EML2 overlapping the first light emitting layer EML1, and a third light emitting stack ST3 may include a third light emitting layer EML3 overlapping the first light emitting layer EML1 and the second light emitting layer EML2.

For example, the first light emitting layer EML1 may be to emit any one selected from among light of a first color, light of a second color, and light of a third color, the second light emitting layer EML2 may be to emit any one selected from among the light of the first color, the light of the second color, and the light of the third color, and the third light emitting layer EML3 may be to emit any one selected from among the light of the first color, the light of the second color, and the light of the third color. According to one or more embodiments, the first light emitting layer EML1, the second light emitting layer EML2, and the third light emitting layer EML3 may be to emit light of the same color or emit light of different colors. For example, the light of the first color may be red light, the light of the second color may be green light, and the light of the third color may be blue light, but the present disclosure is not limited thereto.

In some embodiments, the first light emitting layer EML1 may be to emit light of a plurality of colors of light of a first color, light of a second color, light of a third color, and light of a fourth color; the second light emitting layer EML2 may be to emit light of a plurality of colors of the light of the first color, the light of the second color, the light of the third color, and the light of the fourth color; and the third light emitting layer EML3 may be to emit light of a plurality of colors of the light of the first color, the light of the second color, the light of the third color, and the light of the fourth color. For example, the light of the first color may be red light, the light of the second color may be green light, the light of the third color may be blue light, and the light of the fourth color may be yellow light, but the present disclosure is not limited thereto.

Each light emitting layer EML included in the present embodiments may include a host and a dopant. The light emitting layer EML may be formed by using a phosphorescent and/or fluorescent light emitting material as the dopant in the host material. The host material and the dopant material are not particularly limited as long as they are suitable materials.

The light emitting stack ST may further include at least one intermediate layer overlapping at least one light emitting layer EML. For example, the intermediate layer may include a hole injection layer HIL, a hole transporting layer HTL, and an electron transporting layer ETL. According to one or more embodiments, the hole transporting layer HTL may also serve as the hole injection layer HIL.

The hole injection layer HIL may serve to smoothly or suitably move holes injected from the anode electrode AE, and the hole transporting layer HTL may serve to transport the holes and prevent or reduce the introduction (or injection) electrons. The present disclosure may include any materials of the hole injection layer HIL and/or the hole transporting layer HTL that may be suitably used.

The electron transporting layer ETL may serve to smoothly or suitably transport injected electrodes and smoothly or suitably inject electrons. The electron transporting layer ETL may include a material having suitably high electron affinity and suitably high electron mobility.

A charge generation layer CGL may be positioned between the respective (e.g., adjacent) light emitting stacks ST.

The charge generation layer CGL may be a functional layer serving to adjust charge balance between the respective light emitting stacks ST. Accordingly, the charge generation layer CGL may increase emission efficiency of the light emitting element ED and decrease a driving voltage, by providing charges to each of the first to third light emitting layers EML1, EML2, and EML3.

The charge generation layer CGL may include a first charge generation layer CGL1 positioned between the first light emitting stack ST1 and the second light emitting stack ST2, and a second charge generation layer CGL2 positioned between the second light emitting stack ST2 and the third light emitting stack ST3.

A negative charge generation layer nCGL included in the first charge generation layer CGL1 may be arranged in contact with the first light emitting stack ST1 to supply electrons to the first light emitting layer EML1, and may include a host and a dopant. The host may include an organic material, and the dopant may include a metal material. In one or more embodiments, the negative charge generation layer nCGL may include any materials of the negative charge generation layer nCGL that may be suitably used.

A positive charge generation layer pCGL included in the first charge generation layer CGL1 may be arranged in contact with the second light emitting stack ST2 to supply holes to the second light emitting layer EML2, and may include a host and a dopant. The host may include an organic material, and the dopant may include a metal material. In one or more embodiments, the positive charge generation layer pCGL may include any materials of the positive charge generation layer pCGL that may be suitably used.

A negative charge generation layer nCGL included in the second charge generation layer CGL2 may be arranged in contact with the second light emitting stack ST2 to supply electrons to the second light emitting layer EML2, and a positive charge generation layer pCGL included in the second charge generation layer CGL2 may be arranged in contact with the third light emitting stack ST3 to supply holes to the third light emitting layer EML3. Other overlapping descriptions will not be provided.

In one or more embodiments, in a display device 10 applied to a high-resolution electronic device 1, a plurality of light emitting elements ED may be formed within a relatively narrow area. For example, the first light emitting element ED1, the second light emitting element ED2, and the third light emitting element ED3 may be arranged at a relatively narrow interval.

For example, when a hole injection layer HIL, a hole transporting layer HTL, and/or a charge generation layer CGL included in the display device 10 applied to the high-resolution electronic device 1 are formed as a common layer on an anode electrode, this may cause a leakage current defect in the display device 10. The above-described leakage current defect may be caused by metal materials included in the hole injection layer HIL, the hole transporting layer HTL, and/or the charge generation layer CGL.

For example, when the hole injection layer HIL, the hole transporting layer HTL, and/or the charge generation layer CGL included in the display device 10 applied to the high-resolution electronic device 1 are formed as the common layer on the anode electrode, a current driving at least one of the first to third pixels PX1, PX2, and PX3 arranged at a narrow interval (e.g., with each other) may leak to a neighboring pixel through at least one selected from among the hole injection layer HIL, the hole transporting layer HTL, and the charge generation layer CGL including the dopant materials.

Accordingly, in the display device 10 according to one or more embodiments, the light emitting element layers ELL including the hole injection layer HIL, the hole transporting layer HTL, and the charge generation layer CGL may be positioned in portions overlapping the first to third emission areas EA1, EA2, and EA3 so as to be spaced apart from each other using the insulating layer DIL, and accordingly, the leakage current defect of the display device 10 may be solved (e.g., substantially reduced).

The cathode electrode CE may be positioned on the light emitting element layer ELL. The cathode electrode CE may include a first cathode electrode CE1 and a second cathode electrode CE2 that are stacked in the third direction DR3.

In one or more embodiments, the first cathode electrode CE1 may be positioned on the light emitting element layer ELL so as to be in contact with the light emitting element layer ELL. The first cathode electrode CE1 may be formed to overlap the emission area EA and the non-emission area NLA. For example, the first cathode electrode CE1 may be a common electrode.

The first cathode electrode CE1 may be made of a transparent conductive material (TCO) such as ITO and/or IZO capable of transmitting light therethrough or a semi-transmissive conductive material such as magnesium (Mg), silver (Ag), and/or an alloy of magnesium (Mg) and silver (Ag). When the first cathode electrode CE1 is made of the transparent conductive material and/or the semi-transmissive conductive material, an improvement in light emission efficiency due to a micro cavity may be expected.

In one or more embodiments, the second cathode electrode CE2 may be positioned on the first cathode electrode CE1 so as to be in contact with the first cathode electrode CE1. The second cathode electrode CE2 may be formed to overlap the emission area EA and the non-emission area NLA. The second cathode electrode CE2 may entirely cover the first cathode electrode CE1.

The second cathode electrode CE2 may assist in preventing or reducing a disconnection defect of the first cathode electrode CE1. The second cathode electrode CE2 may include a transparent conductive material (TCO) such as ITO and/or IZO capable of transmitting light therethrough. According to one or more embodiments, the second cathode electrode CE2 may not be provided.

In one or more embodiments, the encapsulation layer TFEL may be positioned on the display element layer DEL. The encapsulation layer TFEL may prevent or reduce permeation of oxygen and/or moisture into the display element layer DEL, and may alleviate a physical shock applied to the display element layer DEL.

The encapsulation layer TFEL may include a first encapsulation layer TFE1, a second encapsulation layer TFE2, and a third encapsulation layer TFE3. The first encapsulation layer TFE1 may be arranged on the cathode electrode CE, the second encapsulation layer TFE2 may be arranged on the first encapsulation layer TFE1, and the third encapsulation layer TFE3 may be arranged on the second encapsulation layer TFE2.

The first encapsulation layer TFE1 may cover a profile of an underlying structure at the same thickness. For example, the shape of the first encapsulation layer TFE1 may follow the outline of the underlying structure and may be of substantially the same thickness throughout. The first encapsulation layer TFE1 may include an inorganic insulating material. For example, the first encapsulation layer TFE1 may include silicon nitride (e.g., Si₃N₄ and/or SiNₓ), silicon oxide (e.g., SiO₂ and/or SiOₓ), silicon oxynitride (e.g., SiON), titanium oxide, aluminum oxide, and/or other suitable inorganic insulating materials.

The second encapsulation layer TFE2 may planarize a step (e.g., unevenness) of an underlying structure. The second encapsulation layer TFE2 may include an organic material. For example, the second encapsulation layer TFE2 may be an organic film made of an acrylic resin, an epoxy resin, a phenolic resin, a polyamide resin, a polyimide resin, and/or the like.

The third encapsulation layer TFE3 may include an inorganic insulating material. For example, the third encapsulation layer TFE3 may include silicon nitride (e.g., Si₃N₄ and/or SiNₓ), silicon oxide (e.g., SiO₂ and/or SiOₓ), silicon oxynitride (e.g., SiON), titanium oxide, aluminum oxide, and/or other suitable inorganic insulating materials.

In one or more embodiments, the color filter layer CFL may be positioned on the encapsulation layer TFEL. The color filter layer CFL may include a first color filter CF1, a second color filter CF2, and a third color filter CF3.

In one or more embodiments, the first color filter CF1 may be positioned in a portion overlapping the first emission area EA1. The first color filter CF1 may be to transmit the light of the first color (e.g., light of a red wavelength band) therethrough. Accordingly, the first color filter CF1 may be to transmit the light of the first color among light emitted from the first light emitting element ED1 therethrough.

In one or more embodiments, the second color filter CF2 may be positioned in a portion overlapping the second emission area EA2. The second color filter CF2 may be to transmit the light of the second color (e.g., light of a green wavelength band) therethrough. Accordingly, the second color filter CF2 may be to transmit the light of the second color among light emitted from the second light emitting element ED2 therethrough.

In one or more embodiments, the third color filter CF3 may be positioned in a portion overlapping the third emission area EA3. The third color filter CF3 may be to transmit the light of the third color (e.g., light of a blue wavelength band) therethrough. Accordingly, the third color filter CF3 may be to transmit the light of the third color among light emitted from the third light emitting element ED3 therethrough.

Accordingly, the light of the first color (e.g., the red light) may be emitted from the first emission area EA1, the light of the second color (e.g., the green light) may be emitted from the second emission area EA2, and the light of the third color (e.g., the blue light) may be emitted from the third emission area EA3.

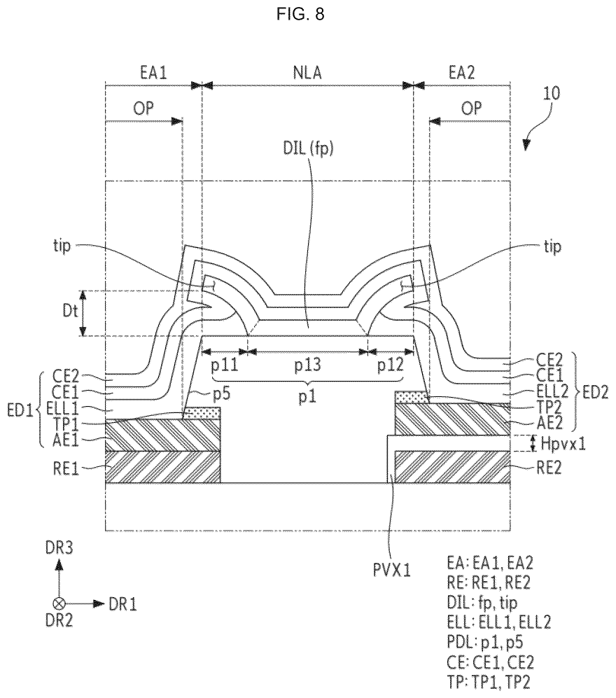

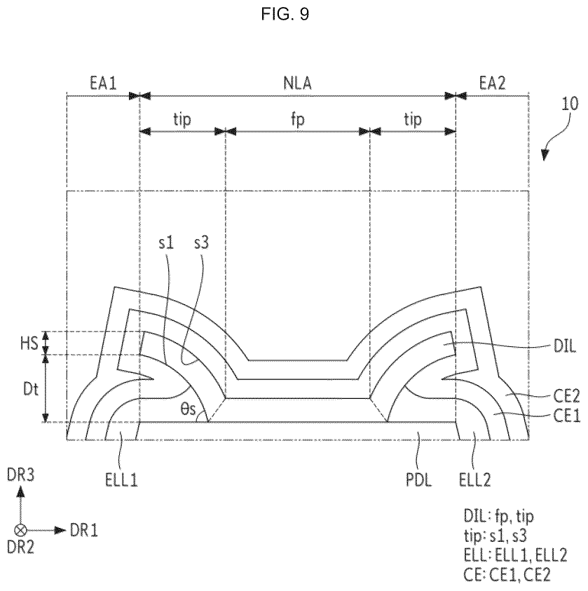

FIG. 8 is an enlarged cross-sectional view of a display element layer of a portion overlapping a non-emission area positioned between a first emission area and a second emission area in FIG. 6, and FIG. 9 is an enlarged cross-sectional view of an insulating layer in FIG. 8.

Referring to FIG. 8, the first anode electrode AE1 may be positioned in contact with the first reflective electrode RE1 in a portion overlapping the first emission area EA1, and the second anode electrode AE2 may be spaced apart from the second reflective electrode RE2 in the third direction DR3 with the first element inorganic layer PVX1 interposed therebetween in a portion overlapping the second emission area EA2.

In one or more embodiments, the first element inorganic layer PVX1 may have a first thickness Hpvx1. Accordingly, the first anode electrode AE1 and the second anode electrode AE2 may have a height difference corresponding to the first thickness Hpvx1 of the first element inorganic layer PVX1 therebetween.

In the display device 10 according to one or more embodiments, by making a distance between the first anode electrode AE1 and the reflective electrode RE and a distance between the second anode electrode AE2 and the reflective electrode RE different from each other, it is possible to increase and/or optimize (e.g., improve) a micro-cavity (or thin film resonance) effect (e.g., aspect).

In one or more embodiments, the residual pattern TP may be entirely surrounded by the light emitting element layer ELL, the anode electrode AE, and the pixel defining layer PDL. According to one or more embodiments, the first residual pattern TP1 and the second residual pattern TP2 may be positioned at different heights. For example, the first residual pattern TP1 and the second residual pattern TP2 may have a height difference corresponding to the first thickness Hpvx1 of the first element inorganic layer PVX1 therebetween.

In a portion overlapping the non-emission area NLA, the pixel defining layer PDL may cover the reflective electrode RE, the anode electrode AE, and the residual pattern TP.

In one or more embodiments, the pixel defining layer PDL may include a first surface p1 and a first side surface p5. The first surface p1 of the pixel defining layer PDL may be a surface (e.g., one surface) facing the insulating layer DIL, and the first side surface p5 of the pixel defining layer PDL may be a surface (e.g., one surface) facing the opening OP.

In one or more embodiments, the first surface p1 of the pixel defining layer PDL may include a first portion p11, a second portion p12, and a third portion p13 depending on structures with which it is in contact. The first portion p11 may be a portion in contact with the first light emitting element layer ELL1, the second portion p12 may be a portion in contact with the second light emitting element layer ELL2, and the third portion p13 may be a surface (e.g., one surface) in contact with the insulating layer DIL. The third portion p13 may be positioned between the first portion p11 and the second portion p12.

The first portion p11 and the second portion p12 may be spaced apart from tips “tip” of the insulating layer DIL in the third direction DR3. For example, the first portion p11 and the second portion p12 may overlap the tips tip of the insulating layer DIL in the third direction DR3.

The first side surface p5 of the pixel defining layer PDL may be entirely covered by the light emitting element layer ELL.

Referring to FIGS. 8 and 9, in one or more embodiments, the insulating layer DIL may be positioned on the pixel defining layer PDL so as to be in contact with the pixel defining layer PDL. The insulating layer DIL may be positioned in a portion overlapping the non-emission area NLA, and may not overlap the opening OP. The insulating layer DIL may have a substantially uniform thickness HS. However, the meaning of the substantially uniform thickness HS described above may have a range within a process error deviation (e.g., process error) of 10%.

In one or more embodiments, the insulating layer DIL may include a flat portion fp and tips “tip.” The flat portion fp of the insulating layer DIL may be a portion in contact with the pixel defining layer PDL. The tips “tip” of the insulating layer DIL may be portions connected to both (e.g., simultaneously) sides (e.g., opposite sides) of the flat portion fp and spaced apart from the pixel defining layer PDL.

For example, the insulating layer DIL may include a tip “tip” positioned toward the first emission area EA1 and a tip “tip” positioned toward the second emission area EA2, and the tip “tip” positioned toward the first emission area EA1 and the tip “tip” positioned toward the second emission area EA2 may be connected to each other through the flat portion fp.

In one or more embodiments, a first inclination angle θs formed by the tip “tip” of the insulating layer DIL and the pixel defining layer PDL may be an acute angle.

For example, the tip “tip” of the insulating layer DIL may include a lower surface s1 and an upper surface s3. The lower surface s1 may be a surface (e.g., one surface) facing the pixel defining layer PDL among surfaces included in the tip “tip”, and the upper surface s3 may be a surface (e.g., one surface) opposing (e.g., facing) the lower surface s1.

The lower surface s1 and the upper surface s3 included in the tip “tip” of the insulating layer DIL may be curved surfaces. For example, the lower surface s1 and the upper surface s3 may have a set or predetermined curvature. The lower surface s1 and the upper surface s3 may have a curved surface shape in which they are concavely formed in a direction toward (e.g., along) a diagonal direction between the first direction DR1 and the third direction DR3.

In a portion overlapping the tip “tip” of the insulating layer DIL, the first inclination angle θs formed by formed by the pixel defining layer PDL and the lower surface s1 may be an acute angle. The first inclination angle θs may be freely adjusted within a suitable acute angle range according to a thickness of the light emitting element layer ELL desired or required for the display device 10.

In one or more embodiments, a distance Dt between the pixel defining layer PDL and the tip “tip” of the insulating layer DIL may become smaller (e.g., may decrease) toward the flat portion fp.

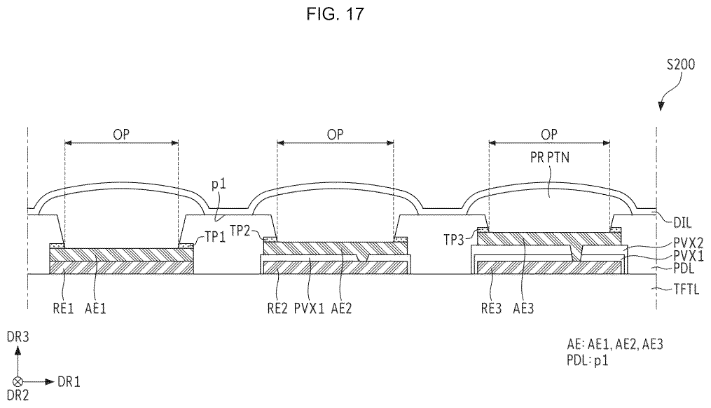

In the display device 10 according to one or more embodiments, the insulating layer DIL may be formed using an organic photoresist pattern PR PTN (see FIG. 17) in the fabricating process. Accordingly, the tip “tip” of the insulating layer DIL according to one or more embodiments may have a curved surface shape in which it is concavely formed in the direction toward the diagonal direction between the first direction DR1 and the third direction DR3.

In one or more embodiments, the first light emitting element layer ELL1 and the second light emitting element layer ELL2 included in the light emitting element layer ELL may be spaced apart from each other with the insulating layer DIL interposed therebetween. The first light emitting element layer ELL1 may be in contact with the tip “tip” of the insulating layer DIL positioned toward the first emission area EA1, and the second light emitting element layer ELL2 may be in contact with the tip “tip” of the insulating layer DIL positioned toward the second emission area EA2.

In one or more embodiments, the cathode electrode CE may cover both (e.g., simultaneously) the tips “tip” and the flat portion fp of the insulating layer DIL.

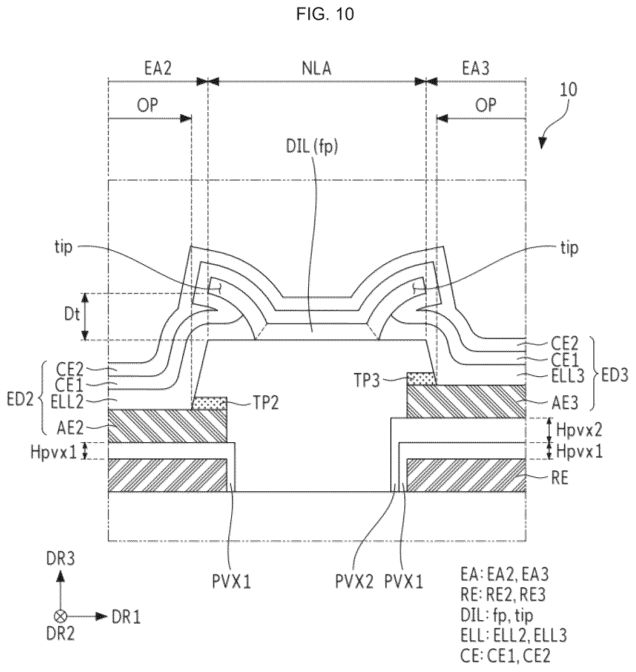

FIG. 10 is an enlarged cross-sectional view of a display element layer of a portion overlapping a non-emission area positioned between the second emission area and a third emission area in FIG. 6.

Referring to FIG. 10, in addition to FIGS. 6 to 9, the second anode electrode AE2 may be spaced apart from the second reflective electrode RE2 with the first element inorganic layer PVX1 interposed therebetween, and the third anode electrode AE3 may be spaced apart from the third reflective electrode RE3 with the first element inorganic layer PVX1 and the second element inorganic layer PVX2 interposed therebetween.

In one or more embodiments, the first element inorganic layer PVX1 positioned in a portion overlapping the second emission area EA2, and the first element inorganic layer PVX1 and the second element inorganic layer PVX2 positioned in a portion overlapping the third emission area EA3, may be spaced apart from each other with the pixel defining layer PDL interposed therebetween.

In one or more embodiments, the first element inorganic layer PVX1 may have a first thickness Hpvx1, and the second element inorganic layer PVX2 may have a second thickness Hpvx2. Accordingly, the second anode electrode AE2 and the third anode electrode AE3 may have a height difference corresponding to the second thickness Hpvx2 of the second element inorganic layer PVX2 therebetween.

In the display device 10 according to one or more embodiments, by making a distance between the second anode electrode AE2 and the reflective electrode RE and a distance between the third anode electrode AE3 and the reflective electrode RE different from each other, it is possible to increase and/or optimize (e.g., improve) a micro-cavity (or thin film resonance) effect (e.g., aspect).

In one or mor embodiments, the second residual pattern TP2 and the third residual pattern TP3 may be positioned at different heights. For example, the second residual pattern TP2 and the third residual pattern TP3 may have a height difference corresponding to the second thickness Hpvx2 of the second element inorganic layer PVX2 therebetween.

In one or more embodiments, the pixel defining layer PDL may cover the second residual pattern TP2 and the third residual pattern TP3. An overlapping and/or redundant description is not provided for brevity.

In one or more embodiments, the insulating layer DIL may include a flat portion fp and tips “tip”. For example, the insulating layer DIL may include a tip “tip” positioned toward the second emission area EA2 and a tip “tip” positioned toward the third emission area EA3, and the tip “tip” positioned toward the first second emission area EA2 and the tip “tip” positioned toward the third emission area EA3 may be connected to each other through the flat portion fp. Other overlapping and/or redundant descriptions will not be provided.

In one or more embodiments, the second light emitting element layer ELL2 and the third light emitting element layer ELL3 may be spaced apart from each other with the insulating layer DIL interposed therebetween. The second light emitting element layer ELL2 may be in contact with the tip “tip” of the insulating layer DIL positioned toward the second emission area EA2, and the third light emitting element layer ELL3 may be in contact with the tip “tip” of the insulating layer DIL positioned toward the third emission area EA3.

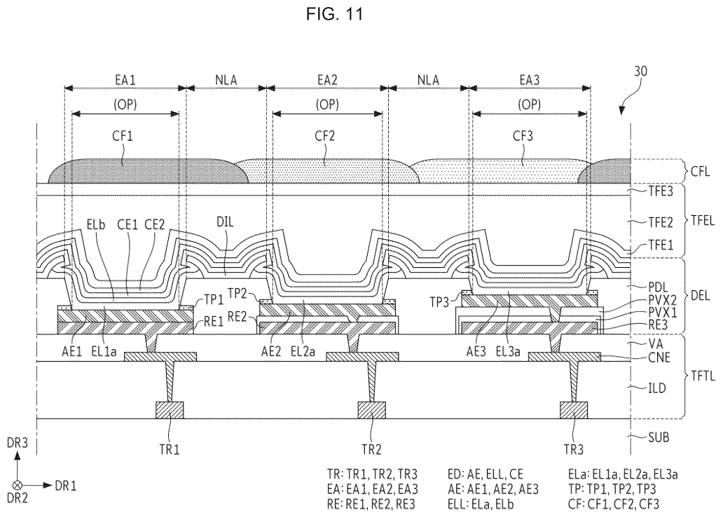

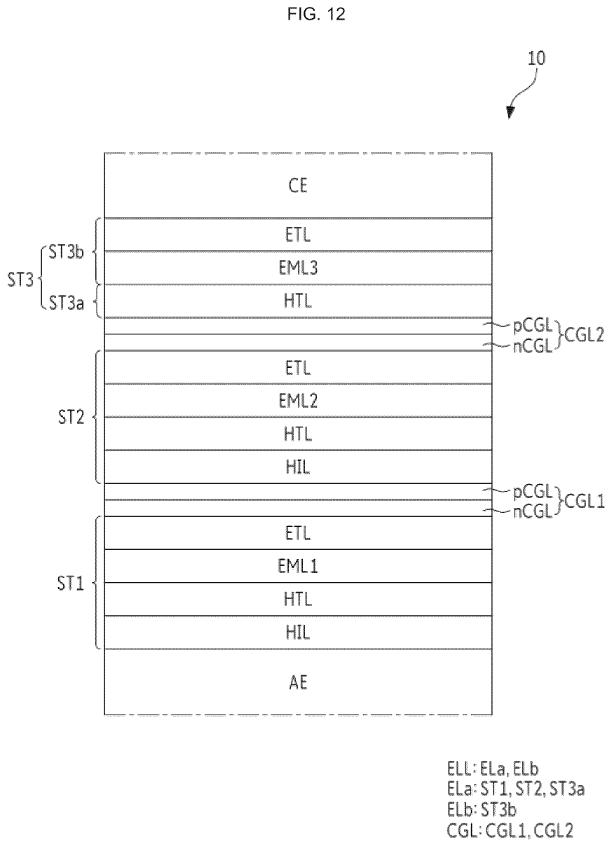

FIG. 11 is a cross-sectional view of a display device according to one or more other embodiment taken along the line X1-X1′ in FIG. 5, and FIG. 12 is an enlarged cross-sectional view of a light emitting element in FIG. 11.

Referring to FIGS. 11 and 12, a light emitting element layer ELL included in a display device 30 may have a different structure from the light emitting element layer ELL included in the display device 10. Hereinafter, a redundant description of a common structure between the display device 10 and the display device 30 will not be provided, and differences between the display device 10 and the display device 30 will be described.

The light emitting element layer ELL included in the display device 30 may include a first layer ELa and a second layer ELb.

The first layer ELa included in the display device 30 may include a first area layer EL1a overlapping the first emission area EA1, a second area layer EL2a overlapping the second emission area EA2, and a third area layer EL3a overlapping the third emission area EA3. The first area layer EL1a, the second area layer EL2a, and the third area layer EL3a may be spaced apart from each other with the pixel defining layer PDL and the insulating layer DIL interposed therebetween.

The second layer ELb included in the display device 30 may be positioned on the first layer ELa. The second layer ELb may be in contact with the first layer ELa, the pixel defining layer PDL, and the insulating layer DIL in a portion overlapping the emission area EA and the non-emission area NLA. For example, the second layer ELb may be a common layer.

As illustrated in FIG. 12, the first layer ELa included in the display device 30 may include all of a hole injection layer HIL, a hole transporting layer HTL, and a charge generation layer CGL included in the light emitting element layer ELL. For example, the first layer ELa included in the display device 30 may include a first stack ST1 including a hole injection layer HIL, a hole transporting layer HTL, a first light emitting layer EML1, and an electron transporting layer ETL, a second stack ST2 including a hole injection layer HIL, a hole transporting layer HTL, a second light emitting layer EML2, an electron transporting layer ETL, a charge generation layer CGL, and a first layer ST3a included in a third stack ST3.

However, this is only an example, and when the light emitting element layer ELL included in the display device 30 has a structure of two stacks or less or a structure of four stacks or more, the first layer ELa included in the display device 30 may include all of the hole injection layer HIL, the hole transporting layer HTL, and the charge generation layer CGL included in the light emitting element layer ELL.

The second layer ELb included in the display device 30 may include an electron transporting layer ETL and a light emitting layer (e.g., a third light emitting layer EML3) positioned closest to the cathode electrode CE. In some embodiments, the second layer ELb included in the display device 30 may further include an electron injection layer positioned between the cathode electrode CE and the electron transporting layer ETL. For example, the second layer ELb included in the display device 30 may not include (e.g., may exclude) the hole injection layer HIL, the hole transporting layer HTL, and the charge generation layer CGL.

In the display device 30 according to one or more embodiments, the first layers ELa of the light emitting element layers ELL including the hole injection layer HIL, the hole transporting layer HTL, and the charge generation layer CGL may be positioned in portions overlapping the first to third emission areas EA1, EA2, and EA3 so as to be spaced apart from each other using the insulating layer DIL, and accordingly, a leakage current defect of the display device 30 may be solved or substantially reduced. An overlapping and/or redundant description of same elements is not provided.

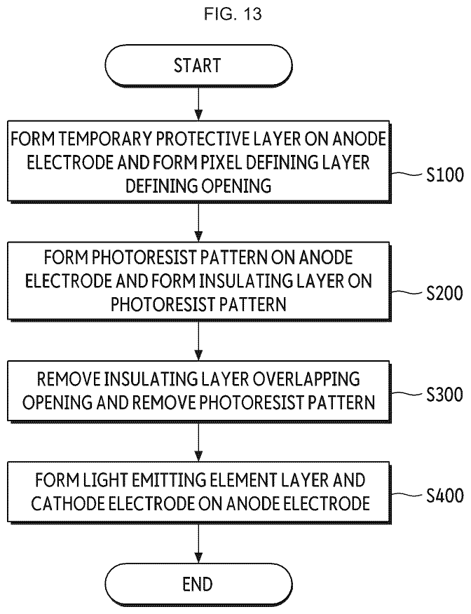

FIG. 13 is a flowchart illustrating a method for fabricating the display element layer in FIG. 6.

Referring to FIG. 13, a method (S1) for fabricating the display device 10 according to one or more embodiments may include forming a temporary protective layer on an anode electrode and forming a pixel defining layer defining an opening (S100), forming a photoresist pattern on the anode electrode and forming an insulating layer on the photoresist pattern (S200), removing the insulating layer overlapping the opening and removing the photoresist pattern (S300), and forming a light emitting element layer and a cathode electrode on the anode electrode (S400).

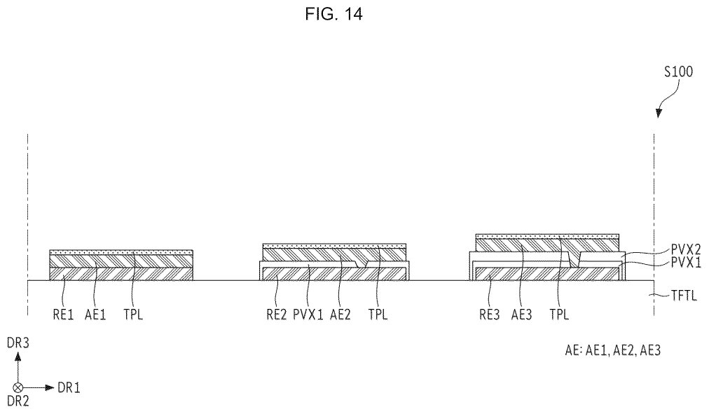

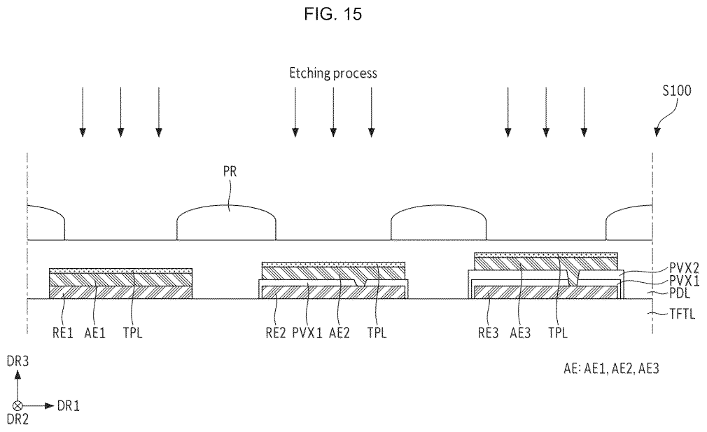

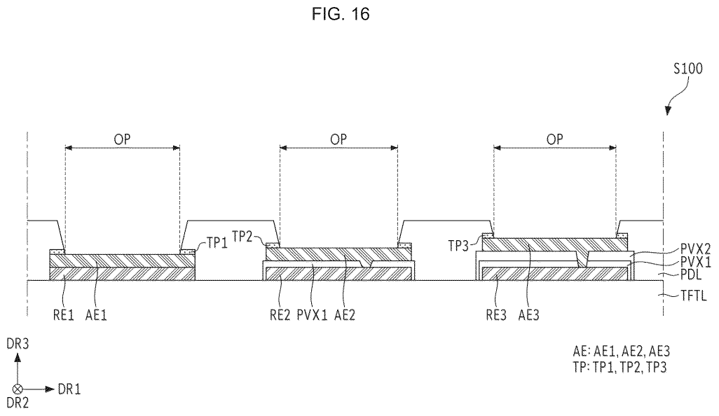

FIGS. 14-16 are each a cross-sectional view illustrating S100 of FIG. 13.

The forming of the temporary protective layer on the anode electrode and the forming of the pixel defining layer defining the opening (S100) is described with reference to FIGS. 14-16.

First, an anode electrode AE and a temporary protective layer TPL are formed on a transistor layer TFTL.

In one or more embodiments, the anode electrode AE may include first to third anode electrodes AE1, AE2, and AE3. In some embodiments, the transistor layer TFTL may be arranged on the substrate SUB, and a structure of the transistor layer TFTL may be the same as described above with reference to FIG. 6.

In one or more embodiments, the first anode electrode AE1 may be formed on a first reflective electrode RE1 so as to be in contact with the first reflective electrode RE1, the second anode electrode AE2 may be spaced apart from a second reflective electrode RE2 with a first element inorganic layer PVX1 interposed therebetween, and the third anode electrode AE3 may be spaced apart from a third reflective electrode RE3 with a first element inorganic layer PVX1 and a second element inorganic layer PVX2 interposed therebetween. Other overlapping descriptions will not be provided.

In one or more embodiments, the first element inorganic layer PVX1 and the second element inorganic layer PVX2 may be formed through a forming process of an insulating film using at least one insulating material (e.g., an inorganic insulating material), for example, as exemplified herein above. Materials and/or methods for forming the first element inorganic layer PVX1 and the second element inorganic layer PVX2 may be variously suitably changed according to one or more embodiments.

In one or more embodiments, the temporary protective layer TPL may entirely cover an upper surface of the anode electrode AE. The temporary protective layer TPL may protect the anode electrode AE so that the anode electrode AE is not damaged (or is not substantially damaged) in a subsequent etching process.

Next, a pixel defining layer PDL is formed on the temporary protective layer TPL. The pixel defining layer PDL may be entirely formed, and may entirely cover the first to third anode electrodes AE1, AE2, and AE3. The pixel defining layer PDL may planarize (or substantially planarize) a profile (e.g., upper surface and/or outline) formed by an underlying structure.

In one or more embodiments, the pixel defining layer PDL may be formed through an applying process using at least one organic material (e.g., as exemplified herein above) and/or may be formed through a forming process of an insulating film using at least one insulating material (e.g., an inorganic insulating material), for example, as exemplified herein above. A material and/or a method for forming the pixel defining layer PDL may be variously suitably changed according to one or more embodiments.

Next, a photoresist PR is formed on the pixel defining layer PDL. In the present process, a plurality of photoresists PR may be formed, and may be spaced apart from each other. The plurality of photoresists PR may be positioned in portions that do not overlap the anode electrode AE.

Subsequently, an etching process is performed.

In one or more embodiments, the pixel defining layer PDL that does not overlap the photoresist PR may be first removed, and the temporary protective layer TPL that does not overlap the photoresist PR may be then removed.

For example, when the pixel defining layer PDL includes an organic material, a wet etching process may be performed as the present process. For example, the wet etching process may be performed using a liquid chemical solution such as a hydrofluoric acid solution, a nitric acid solution, a tetramethylammonium hydroxide solution, a potassium hydroxide solution, and/or the like. In this case, a process of removing the temporary protective layer TPL may be performed concurrently (e.g., simultaneously).

In some embodiments, when the pixel defining layer PDL includes an inorganic material, a dry etching process may be performed as the present process. For example, the dry etching process may be performed through a reactive ion etching (RIE) process using a reaction gas such as CHF₃, CH₃F, CH₂F₂, CHF₆, CF₄, C₂F₆, and/or C₃F₆, and/or a sputtering gas such as Ar and/or O₂/Ar. In this case, an inductively coupled plasma (ICP) source and/or a capacitively coupled plasma (CCP) source may be used as a plasma source. In this case, a process of removing the temporary protective layer TPL may be additionally performed, and a wet etching process may be performed as such a process.

Through the process of the present embodiments, the pixel defining layer PDL may define an opening OP, and may expose the anode electrode AE in a portion overlapping the opening OP. The pixel defining layer PDL may be positioned to cover an edge of the anode electrode AE.

In one or more embodiments, the temporary protective layer TPL may remain in the form of a first residual pattern TP1, a second residual pattern TP2, and a third residual pattern TP3. The residual pattern TP may be positioned to surround the opening OP, and may be positioned between the anode electrode AE and the pixel defining layer PDL.

FIG. 17 is a cross-sectional view illustrating S200 of FIG. 13.

The forming of the photoresist pattern on the anode electrode and the forming of the insulating layer on the photoresist pattern (S200) is described with reference to FIG. 17.

First, a photoresist pattern PR PTN is formed on the anode electrode AE. The photoresist pattern PR PTN may include any materials suitable for use in an organic photoresist.

In one or more embodiments, the photoresist pattern PR PTN may be positioned in a portion overlapping the opening OP, and may have a convex shape toward one side in the third direction DR3. In one or more embodiments, the photoresist pattern PR PTN may entirely fill a space between a plurality of pixel defining layers PDL neighboring to each other, and may be in contact with a portion of a first surface p1 of the pixel defining layer PDL.

In one or more embodiments, the photoresist patterns PR PTN positioned on the first to third anode electrodes AE1, AE2, and AE3 may be spaced apart from each other in the first direction DR1.

Subsequently, an insulating layer DIL is formed on the photoresist pattern PR PTN.

In one or more embodiments, the insulating layer DIL may be entirely formed, and accordingly, may be formed on the photoresist pattern PR PTN and the first surface p1 of the pixel defining layer PDL so as to be in contact with the photoresist pattern PR PTN and the first surface p1 of the pixel defining layer PDL. The insulating layer DIL may be formed at a substantially uniform thickness along a profile of an underlying lower structure (e.g., following an outline of the underlying lower structure). An overlapping description is not provided.

In one or more embodiments, the insulating layer DIL may be formed through a forming process of an insulating film using at least one insulating material (e.g., an inorganic insulating material), for example, as exemplified herein above. A material and/or a method for forming the insulating layer DIL may be suitably changed according to one or more embodiments.

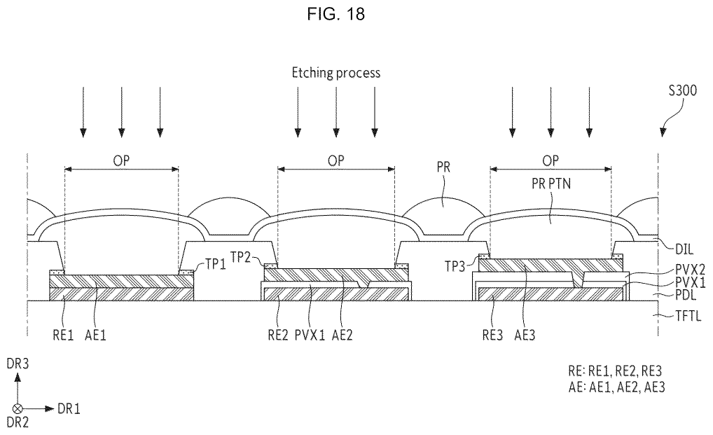

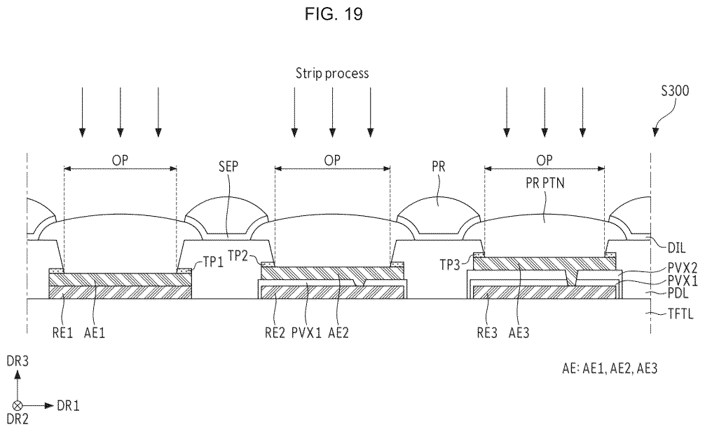

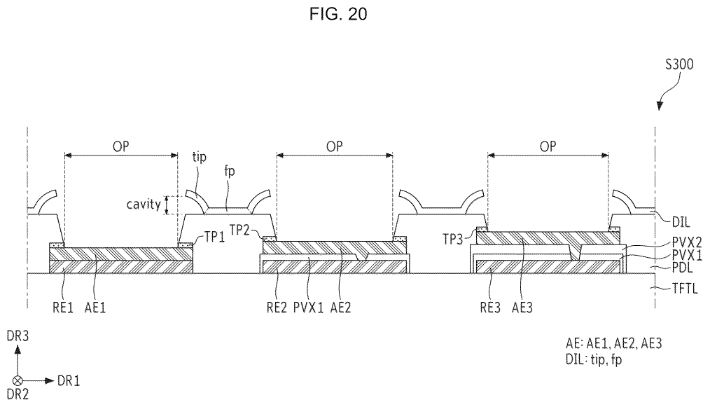

FIGS. 18-20 are each a cross-sectional view illustrating S300 of FIG. 13.

The removing of the insulating layer overlapping the opening and the removing of the photoresist pattern (S300) is described with reference to FIGS. 18-20.

First, a photoresist PR is formed on the insulating layer DIL.

In one or more embodiments, the photoresist PR may be formed to overlap the pixel defining layer PDL in the third direction DR3, and may not overlap the opening OP.

Subsequently, the insulating layer DIL that does not overlap the photoresist PR is removed by performing an etching process. In one or more embodiments, a dry etching process may be performed as the etching process.

In one or more embodiments, the insulating layer DIL positioned in a portion overlapping the opening OP may be removed, and the photoresist pattern PR PTN may be exposed.

Subsequently, a plurality of photoresist patterns PR PTN and a plurality of photoresists PR are removed by performing a photoresist strip process (PR strip process).

In one or more embodiments, the plurality of photoresist patterns PR PTN and the plurality of photoresists PR may all be removed, and the anode electrode AE may be exposed again in a portion overlapping the opening OP.

In one or more embodiments, the insulating layer DIL may include a flat portion fp in contact with the pixel defining layer PDL and tips “tip” protruding toward the openings OP in both (e.g., simultaneously) directions with the flat portion fp interposed therebetween. The tips “tip” of the insulating layer DIL may be spaced apart from the pixel defining layer PDL in the third direction DR3. For example, cavities may be formed between the tips “tip” of the insulating layer DIL and the pixel defining layer PDL.

In one or more embodiments, the insulating layer DIL may be formed on the photoresist pattern PR PTN, and accordingly, may have the tips “tip” having a shape of the photoresist pattern PR PTN. The tips “tip” of the insulating layer DIL may have a curved surface shape, and may have a concave shape in the direction toward the diagonal direction between the first direction DR1 and the third direction DR3.

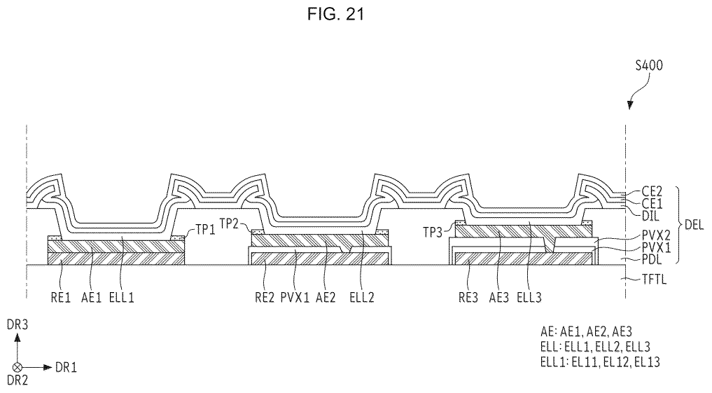

FIG. 21 is a cross-sectional view illustrating S400 of FIG. 13.

The forming of the light emitting element layer and the cathode electrode on the anode electrode (S400) is described with reference to FIG. 21.

First, a light emitting element layer ELL is formed on the anode electrode AE.

In one or more embodiments, the light emitting element layer ELL may be formed through a deposition process using an open mask. The display device 10 according to one or more embodiments includes the insulating layer DIL on the pixel defining layer PDL, and thus, a first light emitting element layer ELL1, a second light emitting element layer ELL2, and a third light emitting element layer ELL3 positioned on the first anode electrode AE1, the second anode electrode AE2, and the third anode electrode AE3, respectively, so as to be spaced apart from each other may be formed without using a separate fine metal mask. Accordingly, the display device 10 according to one or more embodiments may have fabrication easiness (e.g., the manufacturing process of the display device 10 may be simplified).

Subsequently, a cathode electrode CE is formed on the light emitting element layer ELL.

In one or more embodiments, the cathode electrode CE may include a first cathode electrode CE1 and a second cathode electrode CE2.

In one or more embodiments, the first cathode electrode CE1 and the second cathode electrode CE2 may be formed through a deposition process using an open mask. As used herein, an open mask may refer to a mask that is applied to a display and that does not have cover(s) for a display area. The first cathode electrode CE1 and the second cathode electrode CE2 may be entirely formed on the light emitting element layer ELL, and may be a common layer and a common electrode.

Consequently, the display element layer DEL illustrated in FIG. 6 may be fabricated.

Referring again to FIGS. 1-21, the display device 10 according to one or more embodiments includes the first light emitting element layer ELL1, the second light emitting element layer ELL2, and the third light emitting element layer ELL3 positioned in portions respectively overlapping the first to third emission areas EA1, EA2, and EA3 so as to be spaced apart from each other using the insulating layer DIL, and thus, a reliability defect of the display device 10 caused by a leakage current may be solved or substantially reduced.

In one or more embodiments, the display device 10 according to one or more embodiments includes the insulating layer DIL on the pixel defining layer PDL, and may thus include the first light emitting element layer ELL1, the second light emitting element layer ELL2, and the third light emitting element layer ELL3 positioned to be spaced apart from each other even when using the open mask. Accordingly, the display device 10 may have fabrication easiness. An overlapping description of repeating elements is not provided.

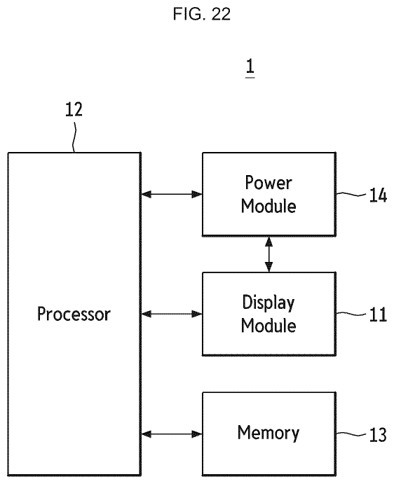

FIG. 22 is a block diagram of an electronic device according to one or more embodiments.

Referring to FIG. 22 in addition to FIGS. 1-21, the display device 10 or 30 according to the embodiments may be applied to one or more suitable electronic devices 1. The electronic device 1 according to one or more embodiments may include the display device 10 or 30, and may further include a module and/or a device having an additional function, in addition to the display device 10 or 30.

The electronic device 1 according to one or more embodiments may include a display module 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

The memory 13 may store data information necessary for an operation of the processor 12 and/or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter and/or a battery device and a power conversion module to convert power supplied by the power supply module to generate power necessary or desired for an operation of the electronic device 1.

At least one of the components of the electronic device 1 may be included in the display device according to the present embodiments. In one or more embodiments, some of individual modules functionally included in one module may be included in the display device, and others of the individual modules may be provided separately from the display device. For example, the display device may include the display module 11, and the processor 12, the memory 13, and the power module 14 may be provided in the form of other devices within the electronic device 1 rather than the display device.

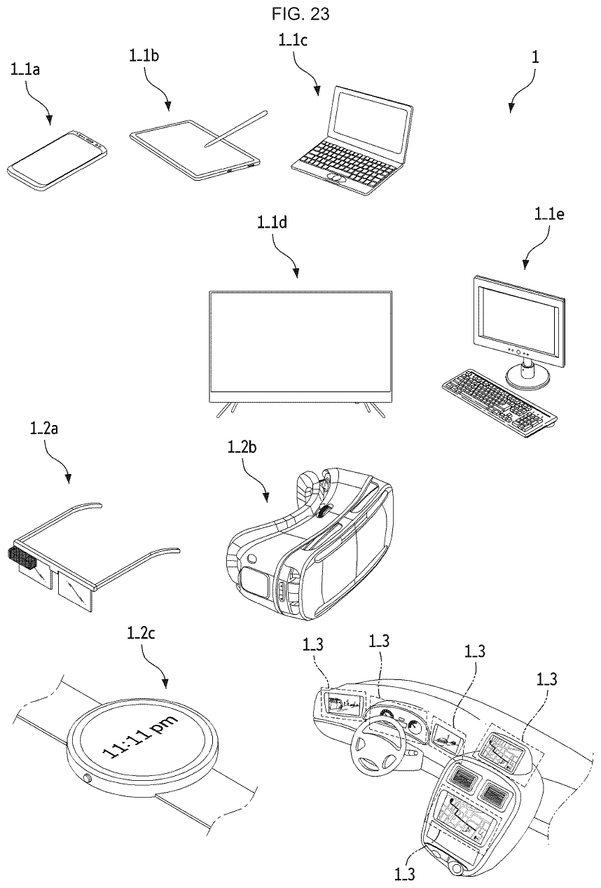

FIG. 23 illustrates schematic views of electronic devices according to one or more suitable embodiments.

Referring to FIG. 23 in addition to FIGS. 1-22, one or more suitable electronic devices 1 to which display devices 10 and 30 according to one or more embodiments may be applied may include not only image display electronic devices such as a smartphone 1_1a, a tablet PC 1_1b, a laptop computer 1_1c, a television 1_1d, and/or a desk monitor 1_1e, but also wearable electronic devices including display modules, such as a smart glasses 1_2a, a head mounted display 1_2b, and/or a smart watch 1_2c, as well as vehicle electronic devices 1_3 including display modules, such as a center information display (CID) arranged on an instrument board, a center fascia, and/or a dashboard of a vehicle and/or a room mirror display.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure is defined by the claims and their equivalents rather than the detailed description described above and all modifications and alterations derived from the claims and their equivalents fall within the scope of the present disclosure.

What is claimed is:

1. A display device comprising:
a substrate comprising an emission area and a non-emission area;
a pixel defining layer on one surface of the substrate;
a first anode electrode and a second anode electrode on the emission area of the substrate and spaced apart from each other with the pixel defining layer therebetween;
a first light emitting element layer on the first anode electrode and a second light emitting element layer on the second anode electrode; and
an insulating layer on the pixel defining layer and between the first light emitting element layer and the second light emitting element layer that are spaced apart from each other,
wherein the insulating layer comprises:
a flat portion in contact with the pixel defining layer; and
a tip extending from one side of the flat portion and spaced apart from the pixel defining layer, and
a lower surface of the tip is a curved surface.

2. The display device of claim 1, wherein the lower surface of the tip and the pixel defining layer are in contact with each other and form an acute angle.

3. The display device of claim 2, wherein a distance between the pixel defining layer and the lower surface of the tip decreases from an edge of the tip toward the flat portion.

4. The display device of claim 3, wherein the pixel defining layer overlaps the non-emission area and defines an opening, and
the insulating layer does not overlap the opening in a direction perpendicular to one surface of the substrate.

5. The display device of claim 4, wherein the tip of the insulating layer further comprises an upper surface opposite the lower surface, and
the upper surface of the tip of the insulating layer is a curved surface.

6. The display device of claim 1, wherein the first light emitting element layer and the second light emitting element layer are in contact with the insulating layer.

7. The display device of claim 6, wherein each of the first light emitting element layer and the second light emitting element layer comprises at least one selected from among a hole injection layer, a hole transporting layer, and a charge transporting layer.

8. The display device of claim 1, wherein the pixel defining layer comprises a first surface facing the insulating layer, and
the first surface comprises a first portion in contact with the first light emitting element layer; a second portion in contact with the second light emitting element layer; and a third portion in contact with the flat portion of the insulating layer.

9. The display device of claim 8, wherein the first portion and the second portion are spaced apart from each other with the third portion therebetween.

10. The display device of claim 1, wherein the first anode electrode and the second anode electrode are at different heights.

11. The display device of claim 1, further comprising:
a first residual pattern on the first anode electrode so as to be in contact with the first anode electrode; and
a second residual pattern positioned on the second anode electrode so as to be in contact with the second anode electrode,
wherein the first residual pattern and the second residual pattern surround an opening defined by the pixel defining layer, and
each of the first residual pattern and the second residual pattern comprises a transparent conductive material.

12. A method for fabricating a display device, the method comprising:
forming a temporary protective layer on an anode electrode and forming a pixel defining layer defining an opening;
forming a photoresist pattern on the anode electrode and forming an insulating layer on the photoresist pattern;
removing the insulating layer overlapping the opening and removing the photoresist pattern; and
forming a light emitting element layer and a cathode electrode on the anode electrode.

13. The method for fabricating a display device of claim 12, wherein in the forming of the photoresist pattern on the anode electrode and the forming of the insulating layer on the photoresist pattern, the insulating layer is on the photoresist pattern so as to be in contact with the photoresist pattern.

14. The method for fabricating a display device of claim 13, wherein in the removing of the insulating layer overlapping the opening and the removing of the photoresist pattern,
the insulating layer comprises a flat portion in contact with the pixel defining layer and tips positioned to be connected to both sides of the flat portion and protruding toward the opening,
the tips of the insulating layer are spaced apart from the pixel defining layer in a direction perpendicular to one surface of the pixel defining layer, and
the tips of the insulating layer have a set curvature.

15. An electronic device comprising:
at least one display device comprising a substrate comprising an emission area and a non-emission area; and
at least one selected from among a display module, a processor, a memory, and a power module connected to the at least one display device,
wherein the at least one display device comprises:
a pixel defining layer on one surface of the substrate;
a first anode electrode and a second anode electrode on the emission area of the substrate and spaced apart from each other with the pixel defining layer therebetween;
a first light emitting element layer on the first anode electrode and a second light emitting element layer on the second anode electrode; and
an insulating layer on the pixel defining layer and between the first light emitting element layer and the second light emitting element layer that are spaced apart from each other,
the insulating layer comprises:
a flat portion in contact with the pixel defining layer; and
a tip extending from one side of the flat portion and spaced apart from the pixel defining layer, and
a lower surface of the tip is a curved surface.

16. The electronic device of claim 15, wherein the lower surface of the tip and the pixel defining layer are in contact with each other and form an acute angle.

17. The electronic device of claim 16, wherein a distance between the pixel defining layer and the lower surface of the tip decreases from an edge of the tip toward the flat portion.

18. The electronic device of claim 17, wherein the pixel defining layer overlaps the non-emission area and defines an opening, and
the insulating layer does not overlap the opening in a direction perpendicular to one surface of the substrate.

19. The electronic device of claim 15, wherein the first light emitting element layer and the second light emitting element layer are in contact with the insulating layer.

20. The electronic device of claim 19, wherein each of the first light emitting element layer and the second light emitting element layer comprises at least one selected from among a hole injection layer, a hole transporting layer, and a charge transporting layer.
